(19) United States
(12) Patent Application Publication
(10) Pub. No.: US 2025/0275411 A1
(43) Pub. Date: Aug. 28, 2025

(54) LIGHT EMITTING DEVICE

(71) Applicant: CANON KABUSHIKI KAISHA, Tokyo (JP)

(72) Inventor: ATSUSHI KANOME, Kanagawa (JP)

(21) Appl. No.: 19/052,529

(22) Filed: Feb. 13, 2025

(30) Foreign Application Priority Data
Feb. 26, 2024 (JP) 2024-026909

(51) Int. Cl. H10K 59/38; H10K 59/80; H10K 102/00

(52) U.S. Cl. CPC H10K 59/38; H10K 59/879; H10K 2102/351

(57) ABSTRACT

A light emitting device includes a light emitting region in which a plurality of sub-pixels are two-dimensionally arranged. Each of the plurality of sub-pixels includes an organic layer including a light emitting layer, a first insulating film arranged on the organic layer, a second insulating film arranged on the first insulating film, and a color filter arranged on the second insulating film. On a cross section passing through the first insulating film, the second insulating film, and the color filter, an upper surface of the second insulating film tilts with respect to a lower surface of the second insulating film.

### BACKGROUND OF THE INVENTION

### Field of the Invention

The present disclosure relates to a light emitting device, a photoelectric conversion device, an electronic apparatus, an illumination device, and a moving body.

### Description of the Related Art

In recent years, needs for wearable display devices applicable to augmented reality (AR), virtual reality (VR), mixed reality (MR), and the like have increased. A wearable display device suitable for these is required to be compact and lightweight. However, if the size or weight is reduced, it is difficult to compensate for a view angle characteristic or light extraction efficiency and, therefore, display quality needs to be improved. Depending on an optical system whose size or weight is reduced, light needs to be emitted from the display device such that it spreads outward or converges inward.

International Publication No. 2017/169961 describes a display device in which an organic layer, a second electrode, a protection film, and a color filter are stacked on a first electrode that is arranged with a tilt.

### SUMMARY OF THE INVENTION

One aspect of the present disclosure provides a light emitting device having a structure advantageous in adjusting a characteristic for each light emitting element.

One of aspects of the present invention provides a light emitting device comprising: a light emitting region in which a plurality of sub-pixels are two-dimensionally arranged, wherein each of the plurality of sub-pixels includes: an organic layer including a light emitting layer; a first insulating film arranged on the organic layer; a second insulating film arranged on the first insulating film; and a color filter arranged on the second insulating film, and on a cross section passing through the first insulating film, the second insulating film, and the color filter, an upper surface of the second insulating film tilts with respect to a lower surface of the second insulating film.

Further features of the present invention will become apparent from the following description of exemplary embodiments with reference to the attached drawings.

### BRIEF DESCRIPTION OF THE DRAWINGS

FIG. 1 is a view exemplarily showing the cross-sectional structure of a light emitting device according to the first embodiment;

FIG. 2A is a view exemplarily showing the cross-sectional structure of the light emitting device according to the first embodiment;

FIG. 2B is a view exemplarily showing the light emitting region of the light emitting device according to the first embodiment;

FIG. 2C is a view exemplarily showing the cross-sectional structure of the light emitting device according to the first embodiment;

FIG. 2D is a view exemplarily showing the light emitting region (display region) of the light emitting device according to the first embodiment;

FIG. 3 is a view exemplarily showing the cross-sectional structure of a light emitting device according to the second embodiment;

FIGS. 4A and 4B is views exemplarily showing the cross-sectional structure of a light emitting device according to the third embodiment;

FIG. 5A is a view exemplarily showing the light emitting region (display region) of a light emitting device according to the fourth embodiment;

FIGS. 5B to 5E are views exemplarily showing the cross-sectional structure of the light emitting device according to the fourth embodiment;

FIGS. 6A to 6F are views exemplarily showing the cross-sectional structure of a light emitting device according to the fifth embodiment;

FIGS. 7A and 7B are views exemplarily showing the cross-sectional structure of a light emitting device according to the sixth embodiment;

FIG. 8A is a view exemplarily showing the cross-sectional structure of the light emitting device according to the sixth embodiment;

FIG. 8B is a view exemplarily showing the light emitting region (display region) of the light emitting device according to the sixth embodiment;

FIG. 8C is a view exemplarily showing the cross-sectional structure of the light emitting device according to the sixth embodiment;

FIG. 8D is a view exemplarily showing the light emitting region (display region) of the light emitting device according to the sixth embodiment;

FIGS. 9A and 9B are views exemplarily showing the cross-sectional structure of a light emitting device according to the seventh embodiment;

FIG. 10A is a view exemplarily showing the light emitting region (display region) of a light emitting device according to the eighth embodiment;

FIGS. 10B to 10E are views exemplarily showing the cross-sectional structure of the light emitting device according to the eighth embodiment;

FIGS. 11A to 11F are views exemplarily showing the cross-sectional structure of a light emitting device according to the ninth embodiment;

FIGS. 12A and 12B are views exemplarily showing the cross-sectional structure of a light emitting device according to the 10th embodiment;

FIGS. 13A and 13B are views exemplarily showing the configuration of a display device according to an embodiment;

FIG. 14 is a view exemplarily showing the configuration of a display device according to an embodiment;

FIGS. 15A and 15B are views exemplarily showing an image capturing device and an electronic apparatus according to an embodiment;

FIGS. 16A and 16B are views exemplarily showing a display device according to an embodiment;

FIGS. 17A and 17B are views exemplarily showing an illumination device and a moving body according to an embodiment;

FIGS. 18A and 18B are views exemplarily showing smartglasses according to an embodiment; and

FIGS. 19A and 19B are views exemplarily showing an image forming device according to an embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate.

Furthermore, in the attached drawings, the same reference numerals are given to the same or similar configurations, and redundant description thereof is omitted.

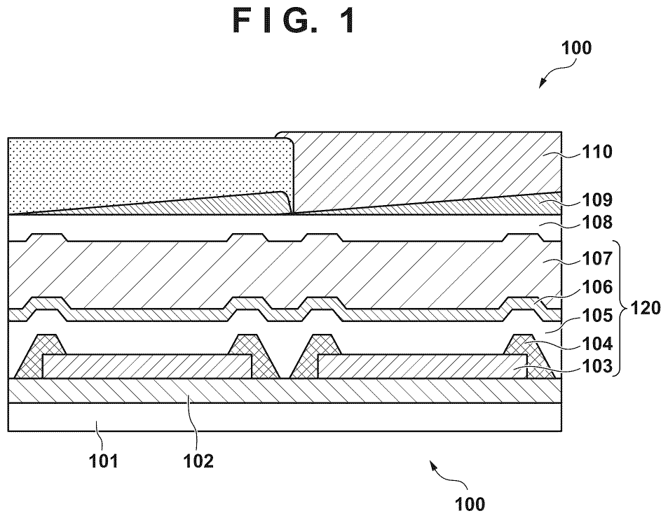

FIG. 1 exemplarily shows the cross-sectional structure of a light emitting device 100 according to the first embodiment. The light emitting device 100 can be configured as a display device. The light emitting device 100 can include a substrate 101, a wiring structure 102 arranged on the substrate 101, and a plurality of light emitting elements 120 arranged on the wiring structure 102. The display device 100 can also include a first insulating film 108 arranged on the plurality of light emitting elements 120, a second insulating film 109 arranged on the first insulating film 108, and a color filter 110 arranged on the second insulating film 109.

The light emitting device 100 includes a light emitting region or a display region, in which the plurality of light emitting elements are two-dimensionally arranged. FIG. 1 shows only two light emitting elements of the plurality of light emitting elements. Each light emitting element can form a sub-pixel. In an example, one pixel can be formed by a plurality of sub-pixels such as an R sub-pixel, a G sub-pixel, and a B sub-pixel. R, G, and B mean red, green, and blue, respectively.

The substrate 101 can be a silicon substrate. The light emitting element 120 can include a first electrode (lower electrode) 103, an organic layer 105 arranged on the first electrode 103, and a second electrode 106 arranged on the organic layer 105. The organic layer 105 includes a light emitting layer. In the light emitting device 100, one first electrode 103 can be provided in correspondence with one light emitting element 120. Also, in the light emitting device 100, the common second electrode 106 can be provided for the plurality of light emitting elements 120. An isolating portion (bank) 104 is arranged between the adjacent first electrodes 103, and the adjacent first electrodes 103 can be isolated from each other by the isolating portion 104. The isolating portion 104 has an opening on the first electrode 103, and is arranged to cover the peripheral portion of the first electrode 103. The light emitting element 120 can include a sealing layer 107 arranged between the second electrode 106 and the first insulating film 108.

The wiring structure 102 can include a plurality of wiring layers. Each wiring layer includes a conductive pattern made of a conductor such as aluminum or copper. An interlayer dielectric film and a via are arranged between a wiring layer and a wiring layer. The first electrode 103 can be made of, for example, a metal such as Al or Ag, an alloy obtained by adding Si, Cu, Ni, Nd, or the like to a metal such as Al or Ag, or ITO, IZO, AZO, or IGZO. Alternatively, the first electrode 103 may be formed by a metal film made of a metal such as Ti, W, Mo, or Au, a layered electrode formed by a metal film made of a metal and a barrier film of an alloy thereof, or a layered electrode formed by the metal film and a transparent oxide film of ITO, IZO, or the like. Also, the first electrode 103 may be formed with a tilt. The first electrode 103 with a tilt can be formed by forming a film made of an electrode material, and after that, forming a tilting resist mask using a gray tone mask, and etching it back. With this method, a tilt according to the tilt of the resist mask is formed (transferred) on the first electrode 103.

The organic layer 105 includes a light emitting layer, and can be formed by a known technique such as vapor deposition or spin coating. Furthermore, the organic layer 105 may be formed by a plurality of layers. More specifically, the plurality of layers can include, other than the light emitting layer, a hole injection layer, a hole transport layer, an electron blocking layer, another light emitting layer, a hole blocking layer, an electron transport layer, and an electron injection layer as a single layer or in an arbitrary combination. The second electrode 106 is arranged on the organic layer 105 and, therefore, can be made of a transparent material (ITO or IZO) such as a transparent conductive oxide with an excellent transmittance. Alternatively, the second electrode 106 can be made of a semitransparent material (a single metal such as aluminum, an alkali metal such as lithium, an alkali earth metal such as magnesium, or a synthetic metal containing these) that reflects part of light.

The sealing layer 107 can be formed by an inorganic material having a high light transmittance and a low oxygen or water permeability, for example, silicon nitride, silicon oxynitride, silicon oxide, aluminum oxide, or titanium oxide, or a layer formed by depositing a plurality of layers thereof. The first insulating film 108 having a light transmittance is formed on the light emitting element 120. The first insulating film 108 can be formed by, for example, a transparent resin formed by spin coating or an inorganic layer made of silicon oxide or silicon oxynitride and having a high light transmittance.

On the cross section shown in FIG. 1 or on a cross section cutting the first insulating film 108, the second insulating film 109, and the color filter 110, the upper surface of the second insulating film 109 tilts with respect to the lower surface of the second insulating film 109. The tilt angle (or tilt angle distribution) of the upper surface of the second insulating film 109 of each sub-pixel can be a tilt angle according to the position of the sub-pixel in the light emitting region. The lower surface of the second insulating film 109 can be parallel to the surface of the substrate 101. Alternatively, the lower surface of the second insulating film 109 can be parallel to the upper surface of the wiring structure 102. Alternatively, the lower surface of the second insulating film 109 can be parallel to the upper surface of the first electrode 103. Alternatively, the lower surface of the second insulating film 109 can be parallel to the upper surface of the first insulating film 108. The upper surface of the second insulating film 109 can be formed by a photolithography step using a gray tone mask having a continuous tone change. If a positive resist is used in this step, it is preferable that, in one sub-pixel, the reticle transmittance is made low in a region where the thickness of the second insulating film 109 should be large, and the reticle transmittance is made high in a region where the thickness of the second insulating film 109 should be small. A tilting structure can be formed by continuously changing the tone in one sub-pixel. In addition, the tilt angle of the second insulating film 109 can be adjusted by adjusting the degree of the tone change or the transmittance difference between the region of the high transmittance and the region of the low transmittance. Note that the adjustment of the reticle transmittance can be performed by changing a dot density distribution formed by a light-shielding film having a resolution equal to or less than the resolution of the exposure apparatus. In the lithography step of forming the second insulating film 109 having a tilting upper surface, a negative resist is used in some cases. In this case, it is preferable that, in one sub-pixel, the reticle transmittance is made low in a region where the thickness of the second insulating film 109 should be small, and the reticle transmittance is made high in a region where the thickness of the second insulating film 109 should be large.

The second insulating film 109 may be formed using an organic film having photosensitivity. Alternatively, the second insulating film 109 may be formed by an inorganic film such as a silicon oxide film or an silicon nitride film. To form the second insulating film 109 using an inorganic film, a tilting resist is formed on the inorganic film by an exposure and development process using a gray tone mask and then etching back the inorganic film. A tilting structure can be formed by continuously changing the tone in one sub-pixel. Thus, the tilt angle of the upper surface of the second insulating film 109 can be adjusted for each sub-pixel. The tilt angle of the upper surface of the second insulating film 109 can adjust whether to emit light from the display device 100 such that the light emitted from the light emitting device 100 or the display device spreads outward from the display device 100 via the optical system.

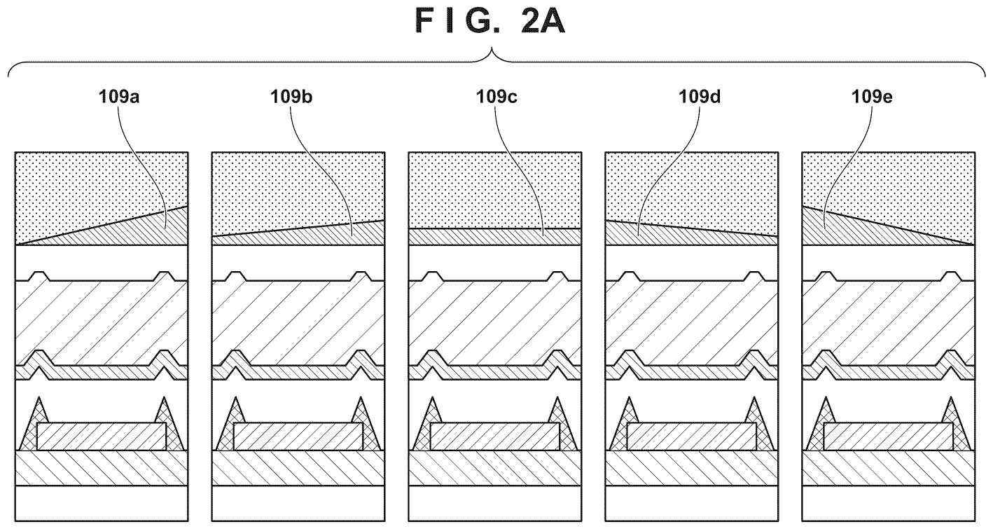

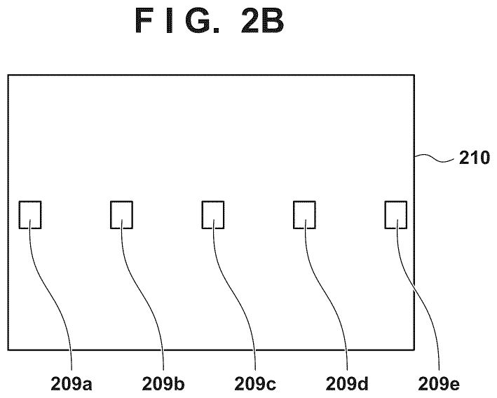

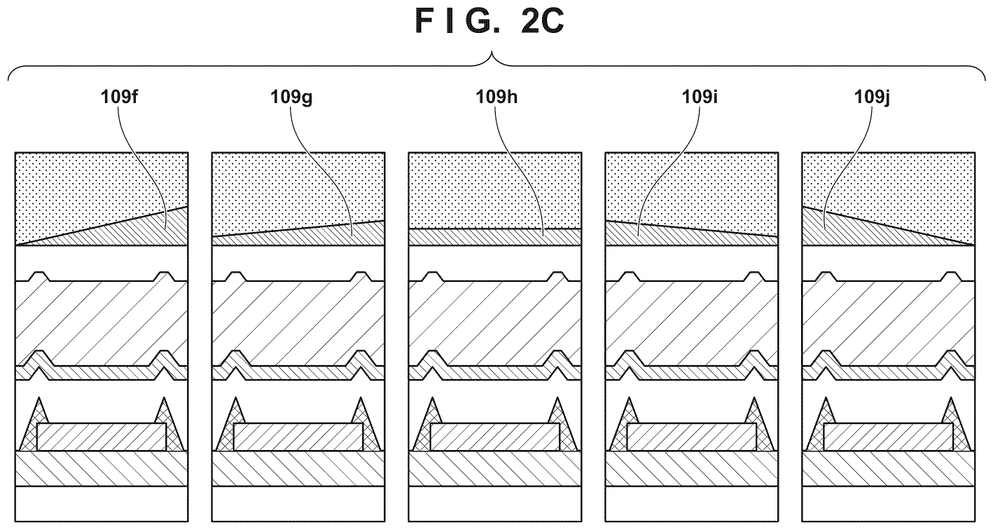

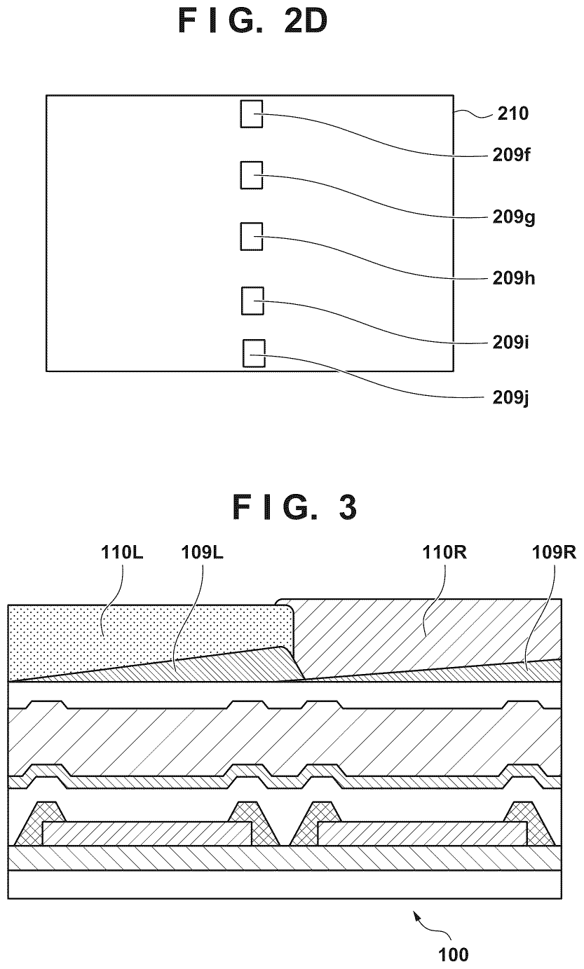

To emit light such that it spreads outward from the light emitting device 100, as schematically shown in FIGS. 2A to 2D, in one sub-pixel, the upper surface of the second insulating film 109 is preferably tilted such that the second insulating film 109 is thick on the center side of the light emitting device and thin on the outer side of the light emitting device. The tilt angle of the upper surface of the second insulating film 109 of each sub-pixel can change depending on the position of the second insulating film 109 in the light emitting device 100. Also, the tilt angle of the upper surface of the second insulating film 109 may change in each sub-pixel. In other words, the upper surface of the second insulating film 109 may be formed by a curved surface in each sub-pixel.

In FIG. 2B, reference numerals 209a, 209b, 209c, 209d, and 209e indicate positions of a plurality of second insulating films 109 or sub-pixels arranged along the X direction in a light emitting region 210 of the light emitting device 100. In FIG. 2A, reference numerals 109a, 109b, 109c, 109d, and 109e indicate second insulating films arranged at the positions indicated by reference numerals 209a, 209b, 209c, 209d, and 209e in FIG. 2B, respectively. In FIG. 2D, reference numerals 209f, 209g, 209h, 209i, and 209j indicate positions of a plurality of second insulating films 109 or sub-pixels arranged along the Y direction in the light emitting region 210 of the light emitting device 100. In FIG. 2C, reference numerals 109f, 109g, 109h, 109i, and 109j indicate second insulating films arranged at the positions indicated by reference numerals 209f, 209g, 209h, 209i, and 209j in FIG. 2D, respectively.

The upper surface of the second insulating film 109 of the sub-pixel arranged at the center portion of the light emitting region 210 of the light emitting device 100 is formed substantially horizontal. The upper surface of the second insulating film 109 can be tilted such that the longer the distance from the center portion is, the larger the tilt angle of the upper surface of the second insulating film 109 of the sub-pixel is. The tilt angle of the upper surface of the second insulating film 109 of the sub-pixel may be understood as the angle of a normal to the upper surface of the second insulating film 109 with respect to a normal to the light emitting region 210 (a normal to the upper surface of the substrate 101). The direction of a vector that projects the normal to the upper surface of the second insulating film 109 of the sub-pixel to the light emitting region 210 can match the direction from the center of the light emitting region 210 to the sub-pixel. To the contrary, light emitted from a sub-pixel in the peripheral region of the light emitting region may be directed to the center of the light emitting region 210. In this case, the direction of a vector that projects the normal to the upper surface of the second insulating film 109 of the sub-pixel to the light emitting region 210 can match the direction from the sub-pixel to the center of the light emitting region 210.

In an aspect, the plurality of sub-pixels forming the light emitting region 210 include a first sub-pixel, and a second sub-pixel arranged between the first sub-pixel and the center of the light emitting region 210. The tilt angle of the upper surface of the second insulating film 109 (for example, 109a) of the first sub-pixel is larger than the tilt angle of the upper surface of the second insulating film 109 (for example, 109b) of the second sub-pixel.

The color filter 110 arranged on the insulating film 109 can have three types of colors, for example, red, green, and blue, but may be white. The color of the color filter 110 is the color (wavelength range) of light transmitted through the color filter 110 and defines the color of the sub-pixel. As for the relationship between the refractive index of the color filter 110 and the refractive index of the second insulating film 109, the materials can be selected such that the refractive index of the color filter 110 is higher. Reversely, if the refractive index of the second insulating film 109 is higher than the refractive index of the color filter 110, the positive/negative sign of the tilt angle is reversed.

The tilt of the upper surface of the second insulating film 109 can cause a change of the thickness of the color filter 110 in the region of each sub-pixel. If the average value of the thickness of the color filter 110 changes between an isolating portion sub-pixels, the intensity of light emitted through the color filter 110 may change for each position in the light emitting region 210. To prevent this, the average value of the thickness of the color filter 110 is preferably equal between the plurality of sub-pixels. However, in an application example in which the intensities of light emitted through the color filters 110 in the light emitting region 210 have a distribution, the average value of the thickness of the color filter 110 can be adjusted between the plurality of sub-pixels in accordance with the distribution.

A transparent layer and/or a microlens may be arranged on the color filter 110. The transparent layer can be formed by applying a transparent resin by spin coating after formation of the color filter 110. Alternatively, the transparent layer may be formed by a layer of an inorganic material having a high light transmittance such as a silicon nitride film or a silicon oxide film.

The microlens can be formed by an exposure and development process. The microlens can be formed by, for example, exposing and developing a transparent resin having photosensitivity using a gray tone mask. Alternatively, the microlens may be formed by a reflow method of shaping a transparent resin by heat. The microlens may be formed by a layer of an inorganic material having a high light transmittance such as a silicon nitride film or a silicon oxide film. For example, after an inorganic layer is formed, a structure having a microlens shape is formed using a resist material on the inorganic layer, and the inorganic layer is etched back via the structure, thereby forming the microlens. The structure having a microlens shape may be formed by exposing and developing the resist material using a gray tone mask, or may be formed by reflowing the resist material by heat.

FIG. 3 shows the cross-sectional structure of a light emitting device 100 according to the second embodiment. Concerning matters that are not mentioned below, the light emitting device 100 according to the second embodiment can have the same configuration as the light emitting device 100 according to the first embodiment. In the second embodiment, the tilt angle (tilt angle distribution) of a second insulating film 109 of each sub-pixel can be a tilt angle according to the color of the sub-pixel (the color of a color filter 110) in addition to the position of the sub-pixel in the light emitting region.

In the second embodiment, the color filter 110 is made of a material according to the color of the color filter 110 (the color of the sub-pixel) and has a refractive index according to the color. That is, the color filters 110 of different colors have different refractive indices. For this reason, if the tilt angles of the upper surfaces of the second insulating films 109 are the same between sub-pixels that are adjacent to each other and have different colors, the angles of light components emitted from the sub-pixels are different. If the angles of the light components emitted from the adjacent sub-pixels are different, image quality may degrade, particularly, the view angle characteristic may degrade.

The second embodiment improves this. In the second embodiment, as exemplarily shown in FIG. 3, color filters 110L and 110R having different colors are arranged adjacent to each other, and second insulating films 109L and 109R under the color filters 110L and 110R have upper surfaces having different tilt angles. For example, if the refractive index of the color filter 110R is higher than the refractive index of the color filter 110L, the tilt angle of the upper surface of the second insulating film 109R is smaller than the tilt angle of the upper surface of the second insulating film 109L. Such tilt angles can be implemented by, for example, adjusting the transmittance of a gray tone mask, like the first embodiment. In the second embodiment as well, a transparent layer and/or a microlens may be arranged on each color filter 110.

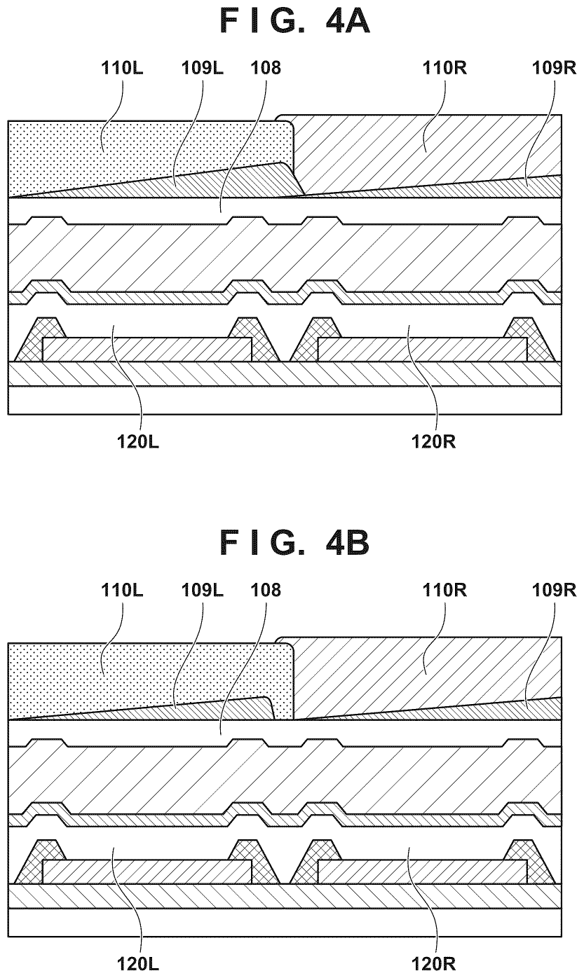

FIGS. 4A and 4B exemplarily show the cross-sectional structure of a light emitting device 100 according to the third embodiment. Concerning matters that are not mentioned below, the light emitting device 100 according to the third embodiment can have the same configuration as the light emitting device 100 according to the first or second embodiment. As exemplarily shown in FIGS. 4A and 4B, a plurality of sub-pixels of the light emitting device 100 include a first sub-pixel and a second sub-pixel, which are adjacent to each other. The first sub-pixel can include a first color filter 110L, and the second sub-pixel can include a second color filter 110R whose color is different from the first color filter 110L. Also, at least one of a second insulating film 109L of the first sub-pixel and a second insulating film 109R of the second sub-pixel can have, between the boundary portion between the first color filter 110L and the second color filter 110R and a portion other than the boundary portion, a structure for reducing color mixture between the first sub-pixel and the second sub-pixel.

This will be described below using more detailed examples. As exemplarily shown in FIGS. 4A and 4B, light emitted from a light emitting element 120R includes not only a component proceeding to the color filter 110R (that is, right above) but also a component proceeding to the adjacent color filter 110L (that is, diagonally above). Particularly, as exemplarily shown in FIGS. 4A and 4B, if the second insulating film has an upper surface tilting to left, like the second insulating film 109R, light emitted from the light emitting element 120R may enter the color filter 110L located on the left side of the color filter 110R on the second insulating film 109R. If light emitted from the light emitting element 120R passes through the color filter 110R and then enters the color filter 110L, most of the light is blocked by the color filters 110R and 110L of two colors and, therefore, no problem occurs. However, light emitted from the light emitting element 120R and enters the color filter 110L without passing through the color filter 110R may be stray light and cause color mixture.

To improve this, in the example shown in FIG. 4A, the tilt angle of the upper surface of the second insulating film 109L at the boundary portion between the first color filter 110L and the second color filter 110R is determined to totally reflect the light emitted from the light emitting element 120R. The tilt angle for total reflection can depend on the angle of light emitted from the light emitting element 120R to the color filter 110L and the refractive index difference between the color filter 110R and the second insulating film 109L.

In the example shown in FIG. 4B, the second insulating film 109L is not arranged at the boundary portion between the first color filter 110L and the second color filter 110R. Hence, light emitted from the light emitting element 120R enters the color filter 110R before it enters the color filter 110L. The light that has passed through the color filter 110R hardly includes components in the band that passes through the color filter 110L, and color mixture can thus be reduced.

The tilt angles of the upper surfaces of the second insulating films 109L and 109R at the boundary portion can be formed by a photolithography step using a gray tone mask having a continuous tone change, like, for example, the tilt angles of the upper surfaces of the second insulating films 109L and 109R in other portions.

In the third embodiment as well, a transparent layer and/or a microlens may be arranged on each of the color filters 110L and 110R.

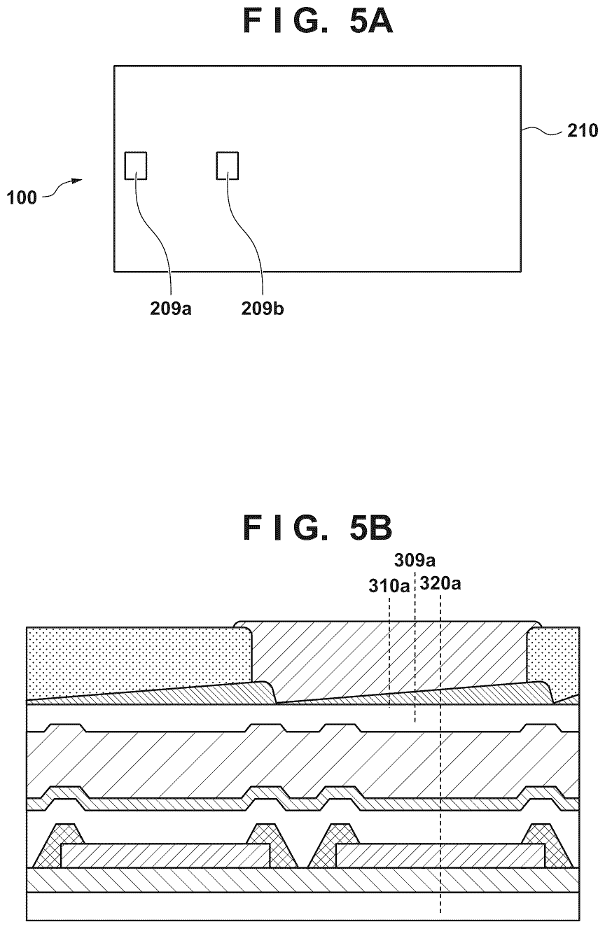

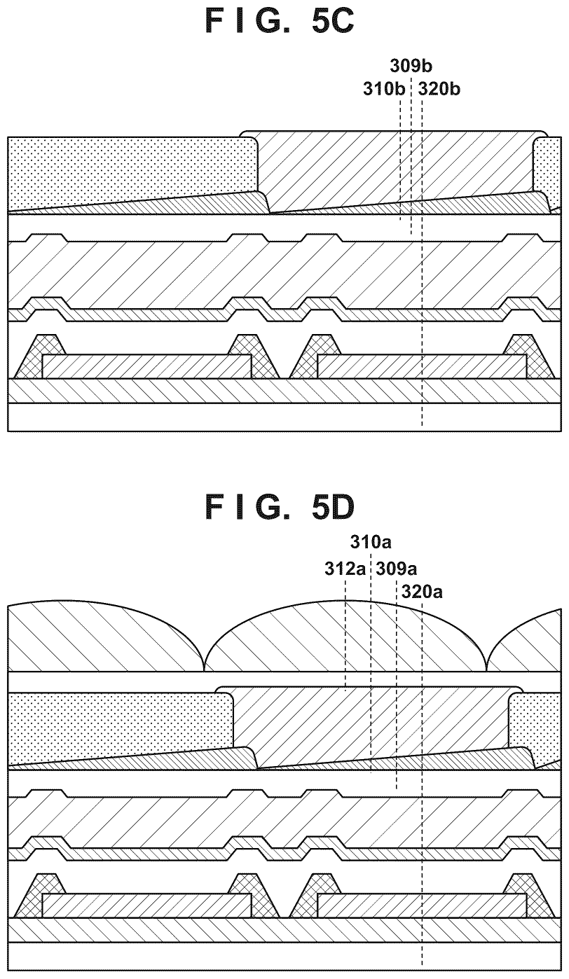

A light emitting device 100 according to the fourth embodiment will be described with reference to FIGS. 5A to 5E. Matters that are not mentioned as the fourth embodiment can comply with the first to third embodiments. FIG. 5A exemplarily shows a plan view of the light emitting device 100. As schematically shown in FIG. 5A, the light emitting device 100 includes a light emitting region 210, and a plurality of sub-pixels are arranged in the light emitting region 210 to form a plurality of rows and a plurality of columns. The plurality of sub-pixels include a first sub-pixel 209a and a second sub-pixel 209b arranged between the first sub-pixel 209a and the center of the light emitting region 210.

FIGS. 5B and 5C schematically show the cross-sectional structure of the first configuration example of the light emitting device 100 according to the fourth embodiment. Here, FIG. 5B schematically shows the cross-sectional structure of the first sub-pixel 209a of the first configuration example, and FIG. 5C schematically shows the cross-sectional structure of the second sub-pixel 209b of the first configuration example. In one sub-pixel 209a, a center position 320a of a light emitting element, a center position 309a of a second insulating film, and a center position 310a of a color filter may be shifted from each other. Also, in another sub-pixel 209b, a center position 320b of a light emitting element, a center position 309b of a second insulating film, and a center position 310b of a color filter may be shifted from each other. In another viewpoint, the mutual shift amount between the center positions 320a, 309a, and 310a in the first sub-pixel 209a is larger than the mutual shift amount between the center positions 320b, 309b, and 310b in the second sub-pixel 209b. In this specification, the center of the light emitting element means the center of an opening provided in an isolating portion 104 in a planar view.

FIGS. 5D and 5E schematically show the cross-sectional structure of the second configuration example of the light emitting device 100 according to the fourth embodiment. Here, FIG. 5D schematically shows the cross-sectional structure of the first sub-pixel 209a of the second configuration example, and FIG. 5E schematically shows the cross-sectional structure of the second sub-pixel 209b of the second configuration example. In one sub-pixel 209a, the center position 320a of the light emitting element, the center position 309a of the second insulating film, the center position 310a of the color filter, and a center 312a of a microlens may be shifted from each other. Also, in another sub-pixel 209b, the center position 320b of the light emitting element, the center position 309b of the second insulating film, the center position 310b of the color filter, and a center 312b of a microlens may be shifted from each other. In another viewpoint, the mutual shift amount between the center positions 320a, 309a, 310a, and 312a in the first sub-pixel 209a is larger than the mutual shift amount between the center positions 320b, 309b, 310b, and 312b in the second sub-pixel 209b.

The configurations as described above can be implemented by, for example, a method using a reticle according to the shift amount as a reticle used in an exposure step for forming the constituent elements or by creating a reticle without a shift and controlling a magnification in an exposure apparatus.

In the fourth embodiment as well, the tilt angle of the upper surface of each second insulating film 109 may be adjusted in accordance with the position of the sub-pixel, the tilt angle of the upper surface of each second insulating film 109 may be adjusted in accordance with the color of the sub-pixel, or a structure for reducing color mixture between adjacent sub-pixels may be formed.

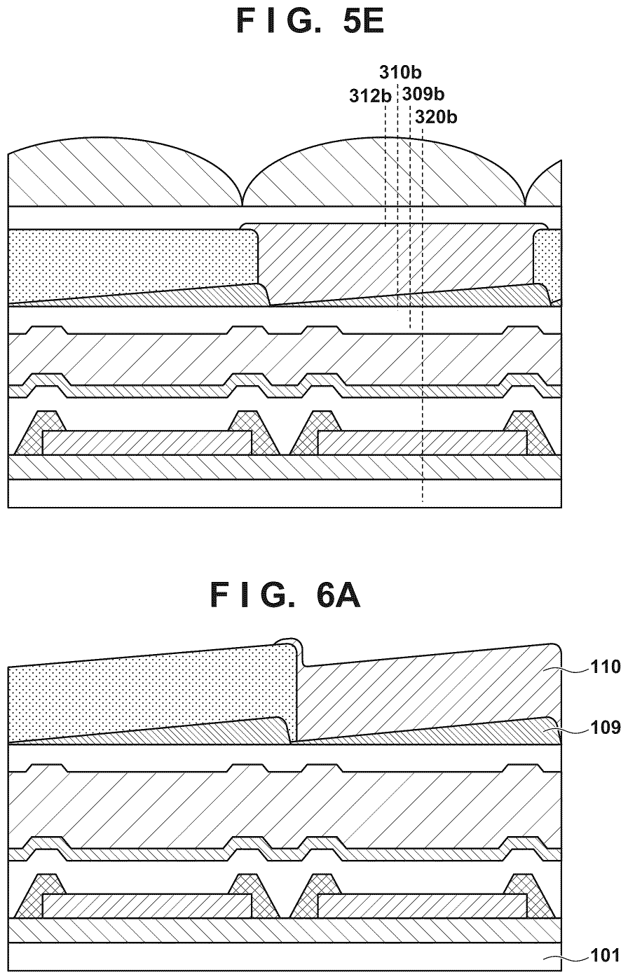

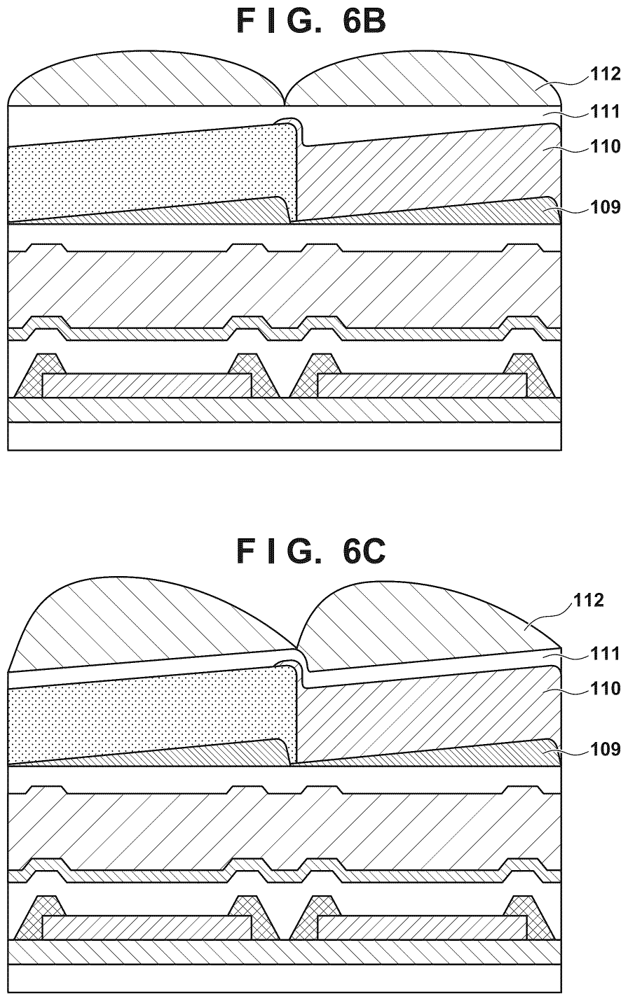

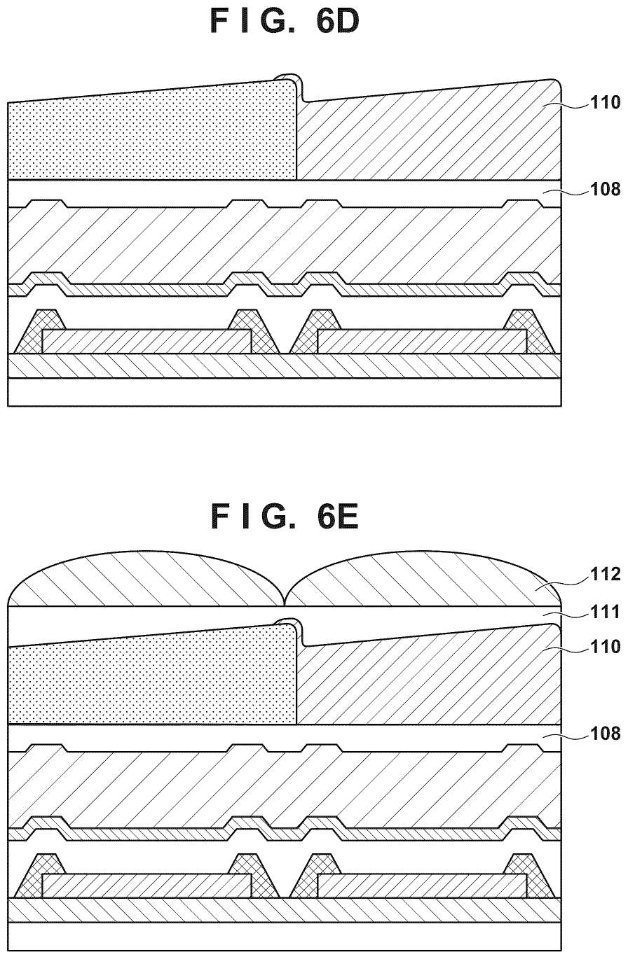

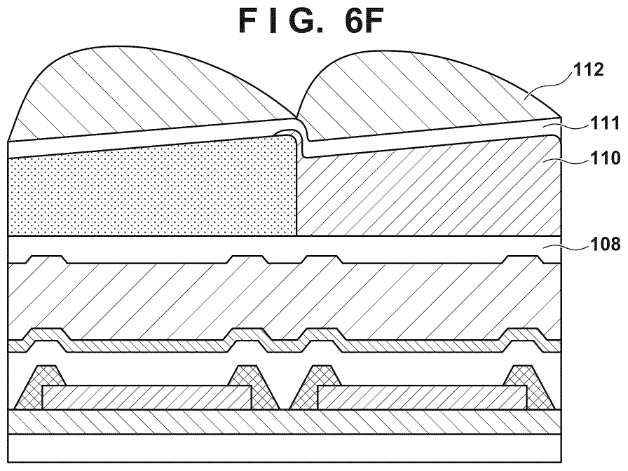

FIGS. 6A to 6F show the schematic cross-sectional structures of a plurality of configuration examples of a light emitting device 100 according to the fifth embodiment. Matters that are not mentioned as the fifth embodiment can comply with any one of the configurations of the first to fourth embodiments, but may be independent of the configurations of the first to fourth embodiments.

In the light emitting device 100 according to the fifth embodiment, a color filter 110 has an upper surface tilting with respect to the upper surface of a substrate 101. In the first to third configuration examples exemplarily shown in FIGS. 6A to 6C, the color filter 110 has an upper surface and a lower surface tilting with respect to the upper surface of the substrate 101. In the first to third configuration examples, the color filter 110 can have an even thickness in each sub-pixel. In the first to third configuration examples, the tilt angle of the upper surface and the lower surface of the color filter 110 can be adjusted or determined in accordance with the position in the light emitting region and/or in accordance with the color. In the first to third configuration examples exemplarily shown in FIGS. 6A to 6C, a normal to (the upper surface and the lower surface of) the color filter 110 tilts with respect to a normal to the light emitting region (display region) (or a normal to the upper surface of the substrate 101). The color filter 110 can be formed using, for example, a gray tone mask, as in a method of forming a second insulating film 109.

As exemplarily shown un FIG. 6B, a transparent film 111 and/or a microlens 112 may be formed on the color filter 110. The transparent film 111 can be formed by, for example, spin coating. The microlens 112 can be formed by, for example, an exposure and development process.

As exemplarily shown in FIG. 6C, the tilting transparent layer 111 and/or the tilting microlens 112 may be provided. The configuration of the tilting microlens 112 may be understood as a configuration in which the center axis of the microlens 112 tilts with respect to the normal to the light emitting region (display region) (or the normal to the upper surface of the substrate 101). The transparent layer 111 can be formed by forming a transparent resin having photosensitivity on the color filter 110 by spin coating and then exposing and developing the transparent resin using a gray tone mask. In addition, the microlens 112 can be formed by an exposure and development process using a gray tone mask or a reflow method. Since the tilt angle of the color filter 110 and the transparent layer 111 under the microlens 112 may change for each sub-pixel, the tilt angle of the microlens 112 may also change for each sub-pixel. However, the tilt angle of the microlens 112 need not always be equal to the tilt angle of the upper surfaces of the second insulating film 109 and the color filter 110. The tilt angle of the lower surface of the microlens 112 can be adjusted for each sub-pixel by adjusting the transmittance of the gray tone mask in a step of forming the transparent layer 111. The transparent layer 111 and the microlens 112 may be made of an inorganic material, and in this case, an inorganic film and an organic film are sequentially formed and, after that, the shape of the organic film is transferred to the inorganic film by etch back.

In the fourth to sixth configuration examples exemplarily shown in FIGS. 6D to 6F, on a cross section cutting a first insulating film 108 and the color filter 110, the upper surface of the color filter 110 tilts with respect to the lower surface of the color filter 110. In this configuration, the second insulating film 109 may not be provided but may be provided.

In the fifth embodiment as well, in one sub-pixel, the center position of the light emitting element, the center position of the second insulating film, the center position of the color filter, and the center position of the microlens may be shifted from each other. Also, in another viewpoint, the shift amount in the first sub-pixel may be larger than the shift amount in the second sub-pixel.

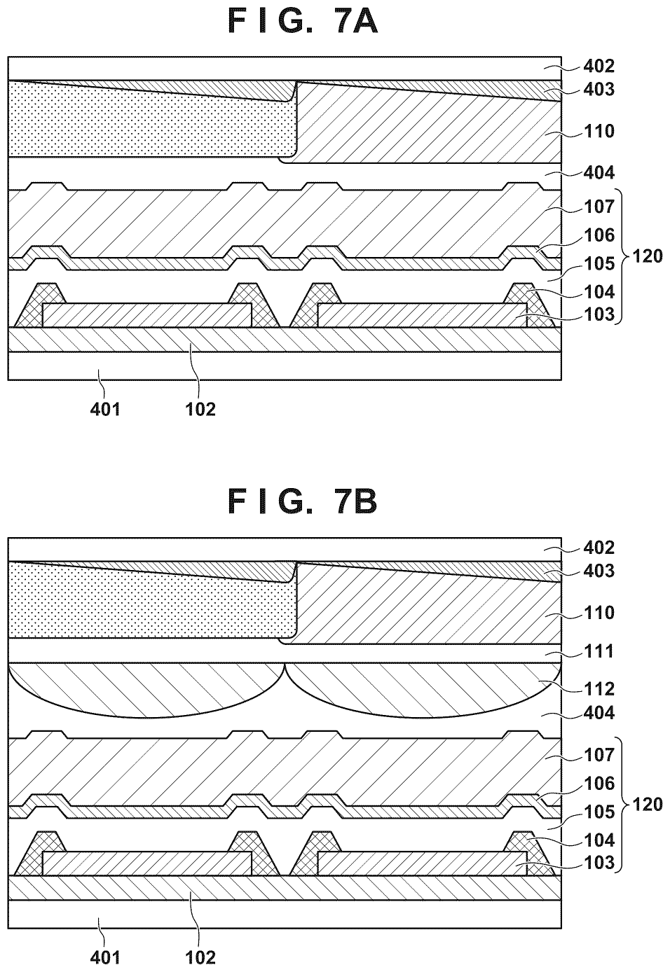

FIGS. 7A and 7B show the cross-sectional structures of two configuration examples of a light emitting device 100 according to the sixth embodiment. The configuration example shown in FIG. 7B has a configuration obtained by adding transparent layers 111 and microlenses 112 to the configuration example shown in FIG. 7A. In a method of manufacturing the light emitting device 100 according to the sixth embodiment, a process up to formation of a light emitting element 120 on a first substrate 401 is the same as in the first embodiment.

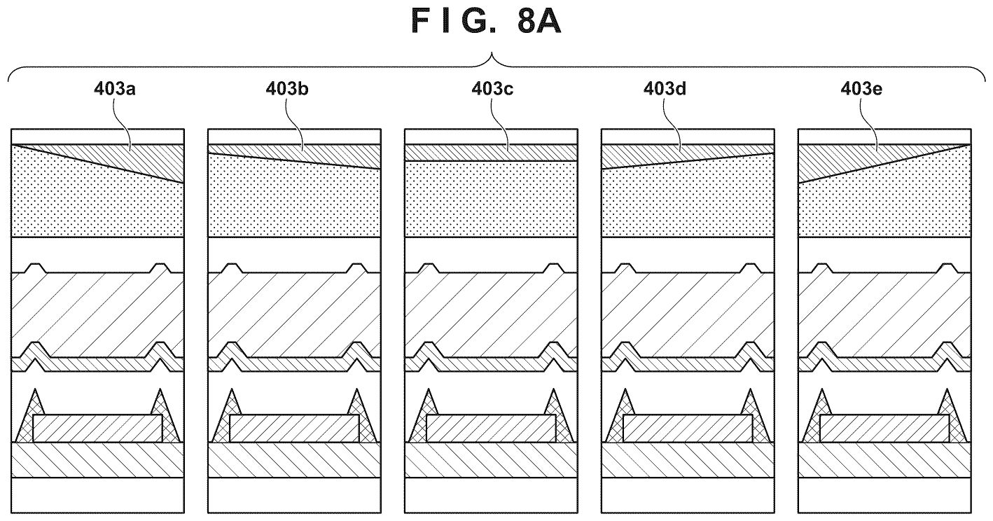

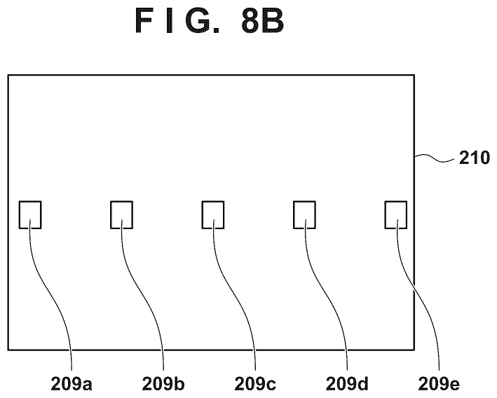

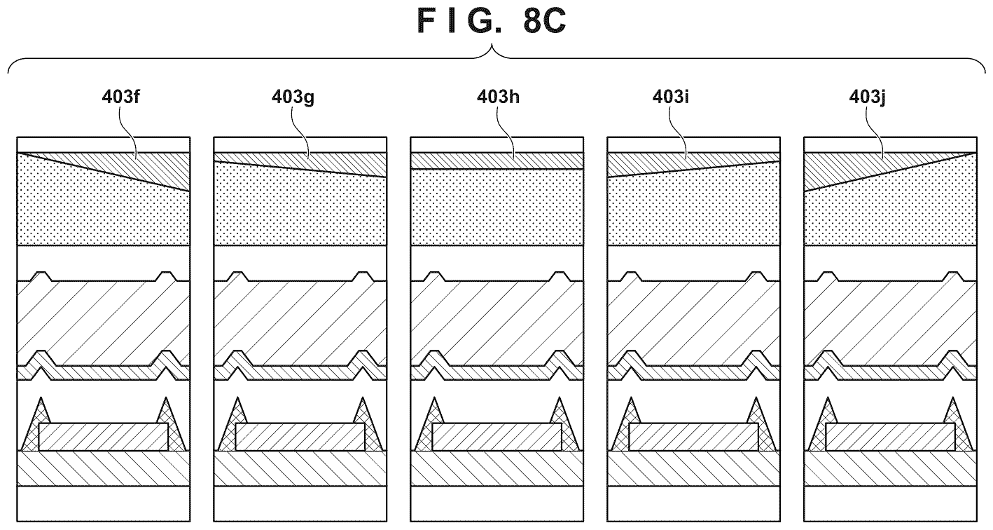

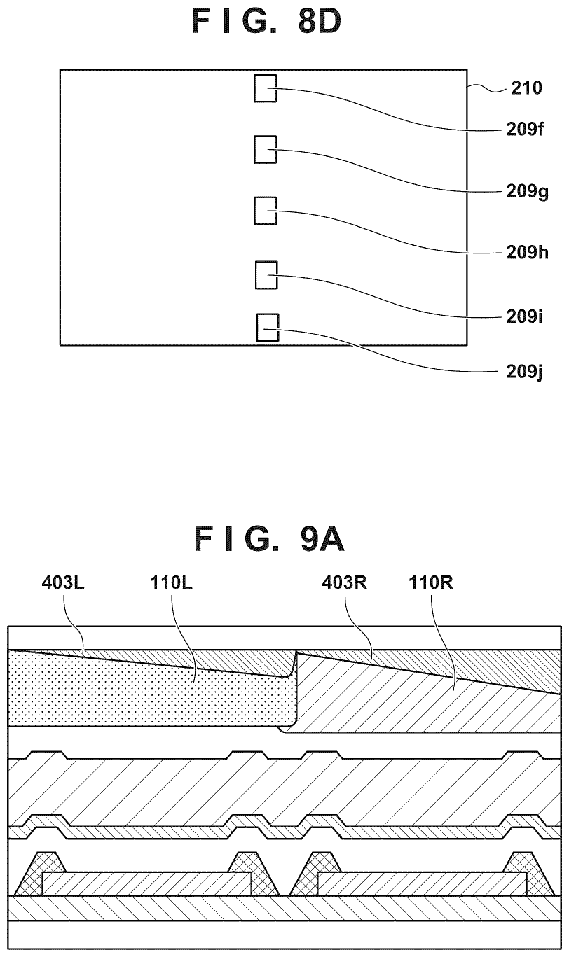

The first substrate 401 can be formed by a silicon substrate. An insulating film 403 having a tilting surface can be formed on a second substrate 402. The second substrate 402 can be formed by a silica glass substrate. As in the first embodiment, the tilt angle of the surface of the insulating film 403 can adjust, in accordance with the configuration of an optical system after emission from the light emitting device 100, whether to emit light such that it spreads outward from the light emitting device 100 or it is emitted to the inside of the light emitting device 100. To emit light such that it spreads outward from the light emitting device 100, as exemplarily shown in FIGS. 8A to 8D, in one sub-pixel, the thickness of the insulating film 403 becomes larger to the center of the light emitting region and smaller to the outside of the light emitting region. In each sub-pixel, the tilt angle of the surface of the insulating film 403 is not even, and the surface of the insulating film 403 may be formed by a curved surface.

In FIG. 8B, reference numerals 209a, 209b, 209c, 209d, and 209e indicate positions of a plurality of insulating films 403 or sub-pixels arranged along the X direction in a light emitting region 210 of the light emitting device 100. In FIG. 8A, reference numerals 403a, 403b, 403c, 403d, and 403e indicate the insulating films 403 arranged at the positions indicated by reference numerals 209a, 209b, 209c, 209d, and 209e in FIG. 8B, respectively. In FIG. 8D, reference numerals 209f, 209g, 209h, 209i, and 209j indicate positions of a plurality of insulating films 403 or sub-pixels arranged along the Y direction in the light emitting region 210 of the light emitting device 100. In FIG. 8C, reference numerals 403f, 403g, 403h, 403i, and 403j indicate the insulating films 403 arranged at the positions indicated by reference numerals 209f, 209g, 209h, 209i, and 209j in FIG. 8D, respectively.

The surface (lower surface) of the insulating film 403 of the sub-pixel arranged at the center portion of the light emitting region 210 of the light emitting device 100 is formed substantially horizontal. The surface of the insulating film 403 can be tilted such that the longer the distance from the center portion is, the larger the tilt angle of the surface of the electronic apparatus of the sub-pixel is. The tilt angle of the surface (lower surface) of the insulating film 403 of the sub-pixel may be understood as the angle of a normal to the surface (lower surface) of the insulating film 403 with respect to a normal to the light emitting region (a normal to the upper surface of the substrate 101). The direction of a vector that projects the normal to the surface of the insulating film 403 of the sub-pixel to the light emitting region 210 can match the direction from the center of the light emitting region 210 to the sub-pixel. To the contrary, light emitted from a sub-pixel in the peripheral region of the light emitting region 210 may be directed to the center of the light emitting region 210. In this case, the direction of a vector that projects the normal to the surface (lower surface) of the insulating film 403 of the sub-pixel to the light emitting region 210 can match the direction from the sub-pixel to the center of the light emitting region 210.

In an aspect, the plurality of sub-pixels forming the light emitting region 210 include a first sub-pixel, and a second sub-pixel arranged between the first sub-pixel and the center of the light emitting region 210. The tilt angle of the surface of the insulating film 403 (for example, 209a) of the first sub-pixel is larger than the tilt angle of the surface of the insulating film 403 (for example, 209b) of the second sub-pixel.

The insulating film 403 having the tilting surface (lower surface) can be formed by photolithography using a gray tone mask, like the second insulating film in the first embodiment. Also, in each sub-pixel, the tilt angle of the insulating film 403 may be adjusted. The insulating film 403 may be formed using an organic film having photosensitivity. Alternatively, the insulating film 403 may be formed by an inorganic film such as a silicon oxide film or an silicon nitride film. To form the insulating film 403 using an inorganic film, a tilting resist is formed on the inorganic film by an exposure and development process using a gray tone mask and then etching back the inorganic film.

As exemplarily shown in FIGS. 7A and 7B, a color filter 110 can be formed on the insulating film 403 formed on the second substrate 402. The color filter 110 can have three types of colors, for example, red, green, and blue, but may be white. As for the relationship between the refractive index of the color filter 110 and the refractive index of the insulating film 403, the materials can be selected such that the refractive index of the color filter 110 is higher, but the present invention is not limited to this. If the refractive index of the insulating film is higher, the positive/negative sign of the tilt angle is reversed.

After that, the side of the first substrate 401, with the light emitting element 120 formed thereon, on the side of the light emitting element 120 and the side of the second substrate 402, with the insulating film 403 and the color filter 110 formed thereon, on the side of the color filter 110, can be bonded with a layer 404 intervening therebetween. The layer 404 has a high light transmittance, and has a function as a planarizing layer and a function as an adhesive.

As exemplarily shown in FIG. 7B, a transparent layer 111 and a microlens 112 may be arranged between the color filter 110 and the layer 404. To obtain this structure, first, the color filter 110 is formed on the second substrate 402, and a transparent resin is applied by spin coating, thereby forming the transparent layer 111. Alternatively, the transparent layer 111 may be formed by a layer of an inorganic material. After that, the microlens 112 can be formed by an exposure and development process. After the microlens 112 is formed, the microlens 112 and the light emitting element 120 can be bonded with the layer 404 intervening therebetween.

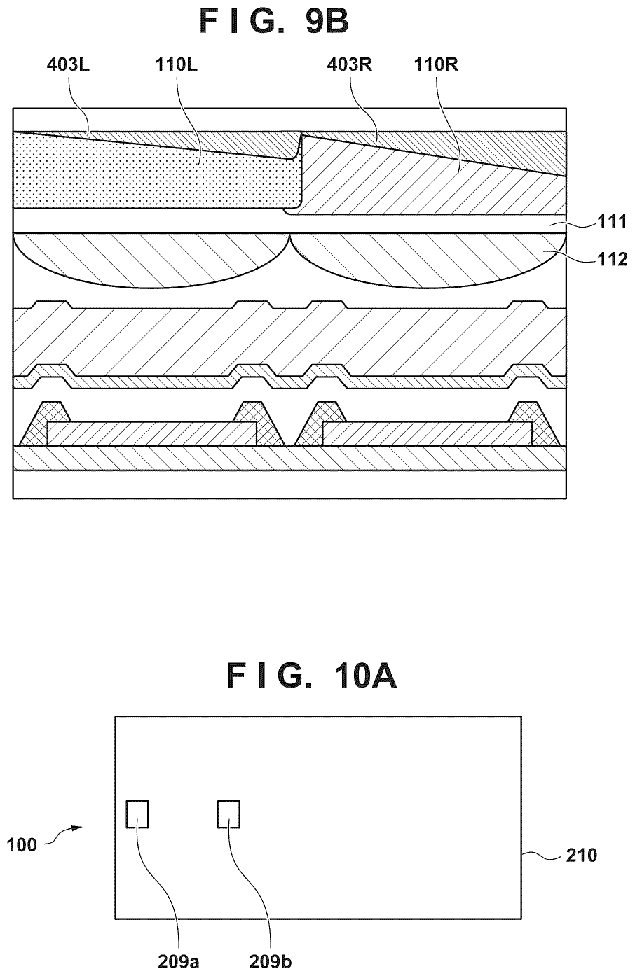

FIGS. 9A and 9B show the cross-sectional structures of two configuration examples of a light emitting device 100 according to the seventh embodiment. The light emitting device 100 according to the seventh embodiment is common to the sixth embodiment except that the tilt angle of an insulating film 403 is adjusted in accordance with the color of a color filter. Matters that are not mentioned as the seventh embodiment can comply with the first to sixth embodiments.

Since the constituent material of the color filter changes between colors, the refractive index changes between colors. For this reason, if two color filters having different colors are adjacent to each other, and the tilt angles of the insulating films 403 substantially equal, the angles of light emitted from the two adjacent color filters are different. This may cause image quality degradation.

The seventh embodiment is advantageous for solving this problem. If a color filter 110L and a color filter 110R, which have different colors, are ranged adjacent to each other, and the refractive index of the color filter 110R is higher than the refractive index of the color filter 110L, the tilt angle of an insulating film 403R is smaller than the tilt angle of an insulating film 403L. The tilt angles can be implemented by adjusting the transmittance distribution of a gray tone mask in an exposure process for forming the insulating films 403.

In the seventh embodiment as well, the tilt angle of the insulating film 403 of a sub-pixel can be adjusted in accordance with the position of the sub-pixel. In the seventh embodiment as well, a transparent layer 111 and a microlens 112 may be provided, as exemplarily shown in FIG. 9B.

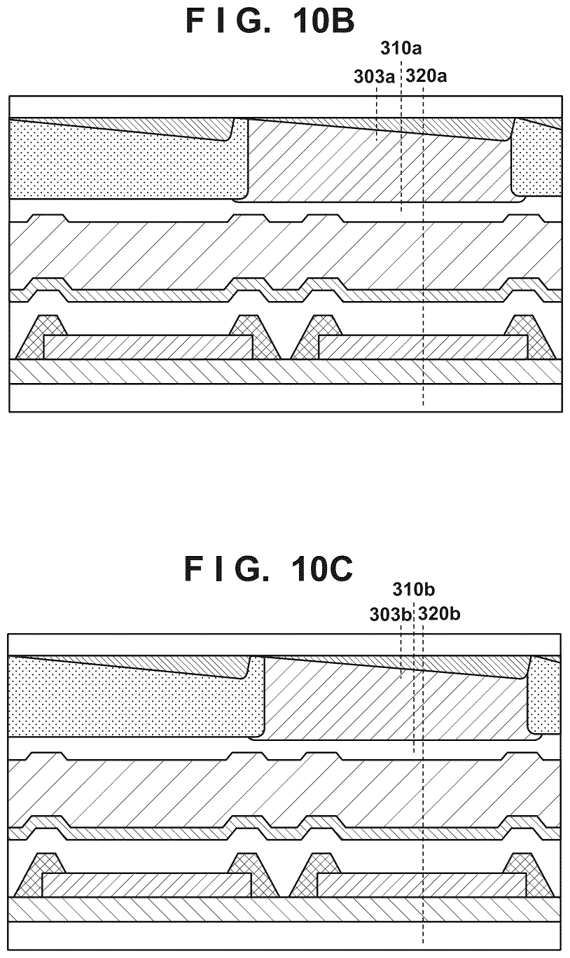

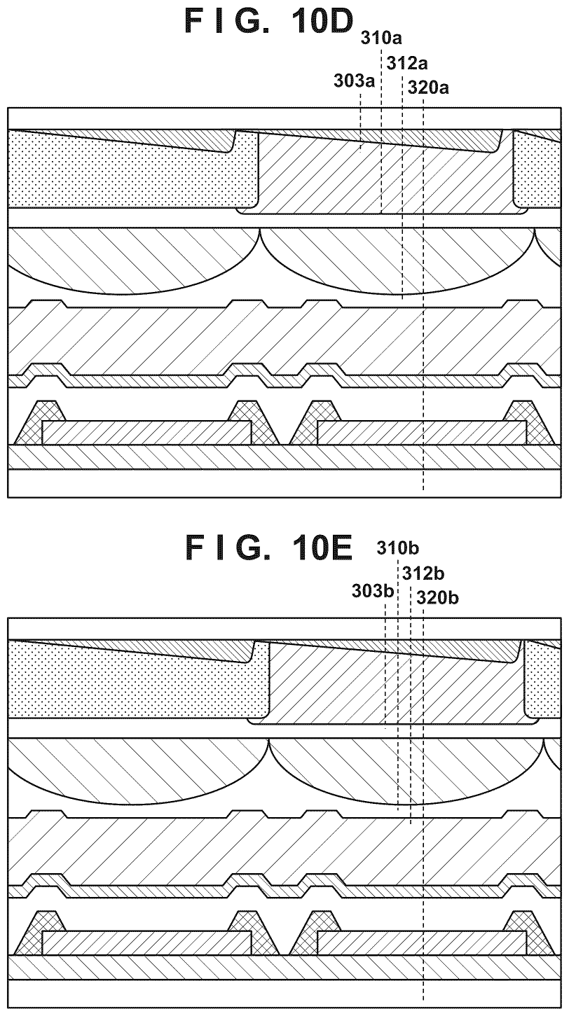

A light emitting device 100 according to the eighth embodiment will be described with reference to FIGS. 10A to 10E. Matters that are not mentioned as the eighth embodiment can comply with the first to seventh embodiments. FIG. 10A exemplarily shows a plan view of the light emitting device 100. As schematically shown in FIG. 10A, the light emitting device 100 includes a light emitting region 210, and a plurality of sub-pixels are arranged in the light emitting region 210 to form a plurality of rows and a plurality of columns. The plurality of sub-pixels include a first sub-pixel 209a and a second sub-pixel 209b arranged between the first sub-pixel 209a and the center of the light emitting region 210.

FIGS. 10B and 10C schematically show the cross-sectional structure of the first configuration example of the light emitting device 100 according to the eighth embodiment. Here, FIG. 10B schematically shows the cross-sectional structure of the first sub-pixel 209a of the first configuration example, and FIG. 10C schematically shows the cross-sectional structure of the second sub-pixel 209b of the first configuration example. In one sub-pixel 209a, a center position 320a of a light emitting element, a center position 303a of an insulating film 403R, and a center position 310a of a color filter 110R may be shifted from each other. Also, in another sub-pixel 209b, a center position 320b of a light emitting element, a center position 303b of the insulating film 403R, and a center position 310b of the color filter 110R may be shifted from each other.

It is possible to adjust, in accordance with the configuration of an optical system after emission from the light emitting device 100, whether to emit light such that it spreads outward from the light emitting device 100 or it is emitted to the inside of the light emitting device 100. In any case, in a sub-pixel close to an end of the light emitting region 210 of the light emitting device 100, light is emitted more obliquely and, therefore, the possibility that stray light occurs is high. Hence, the mutual shift amount between the center positions 320a, 303a, and 310a in the first sub-pixel 209a is preferably larger than the mutual shift amount between the center positions 320b, 303b, and 310b in the second sub-pixel 209b. Also, it is preferable that the closer the position is to the end of the light emitting region 210, in other words, the more the position is apart from the center of the light emitting region 210, the larger the shift amount is. This can reduce stray light.

The configurations as described above can be obtained by, for example, a method using a reticle according to the shift amount as a reticle used in an exposure step for forming the constituent elements or by creating a reticle without a shift and controlling a magnification in an exposure apparatus.

FIGS. 10D and 10E schematically show the cross-sectional structure of the second configuration example of the light emitting device 100 according to the eighth embodiment. Here, FIG. 10D schematically shows the cross-sectional structure of the first sub-pixel 209a of the second configuration example, and FIG. 10E schematically shows the cross-sectional structure of the second sub-pixel 209b of the second configuration example. In one sub-pixel 209a, the center position 320a of the light emitting element, the center position 303a of the insulating film 403R, the center position 310a of the color filter 110R, and a center position 312a of the microlens 112 may be shifted from each other. Also, in another sub-pixel 209b, the center position 320b of the light emitting element, the center position 303b of the insulating film 403R, the center position 310b of the color filter 110R, and a center position 312b of the microlens 112 may be shifted from each other. In another viewpoint, the mutual shift amount between the center positions 320a, 303a, 310a, and 312a in the first sub-pixel 209a is larger than the mutual shift amount between the center positions 320b, 303b, 310b, and 312b in the second sub-pixel 209b.

The configurations as described above can be obtained by, for example, a method using a reticle according to the shift amount as a reticle used in an exposure step for forming the constituent elements or by creating a reticle without a shift and controlling a magnification in an exposure apparatus.

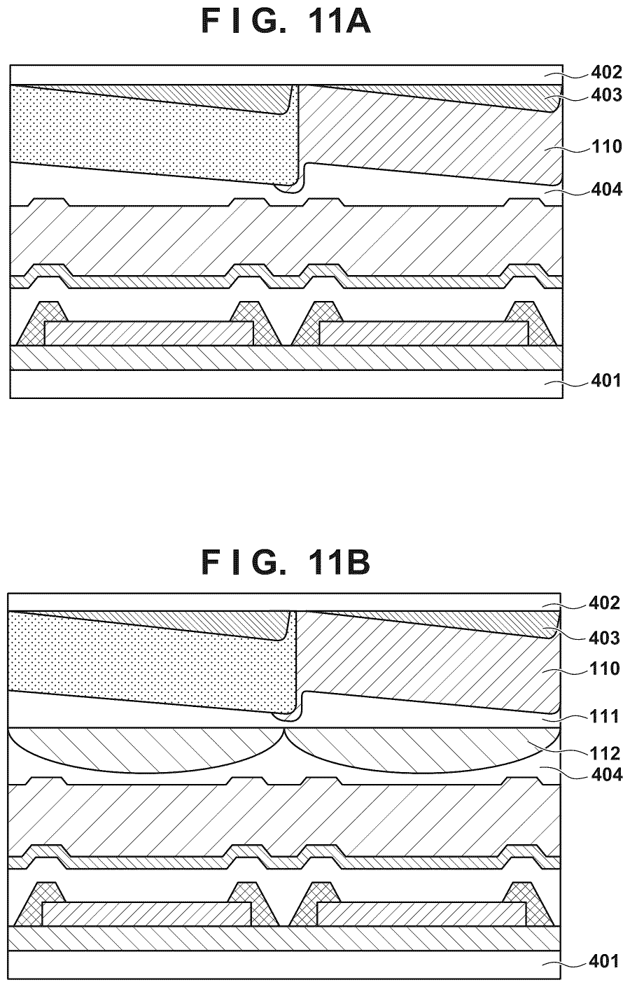

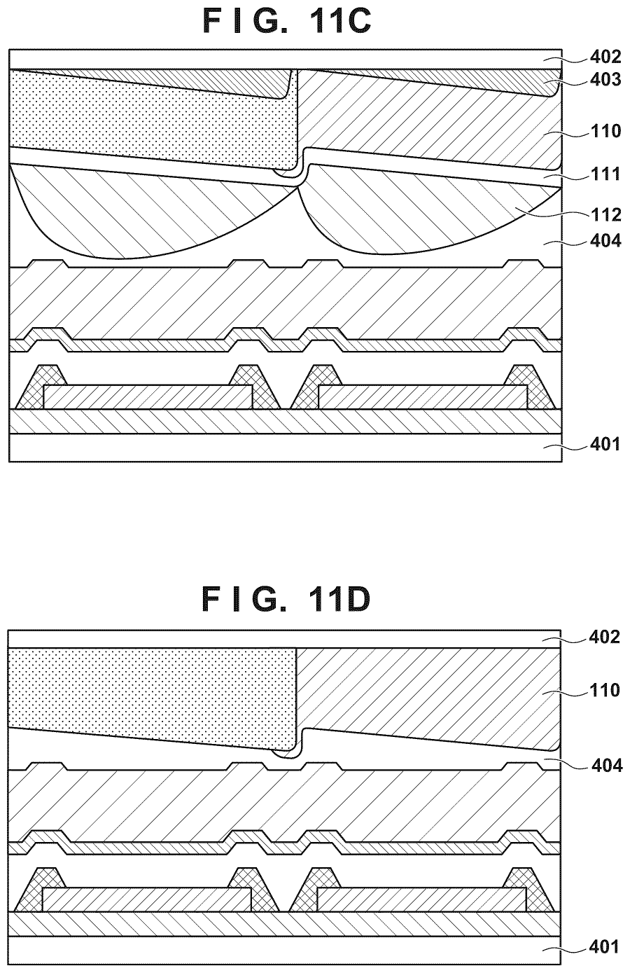

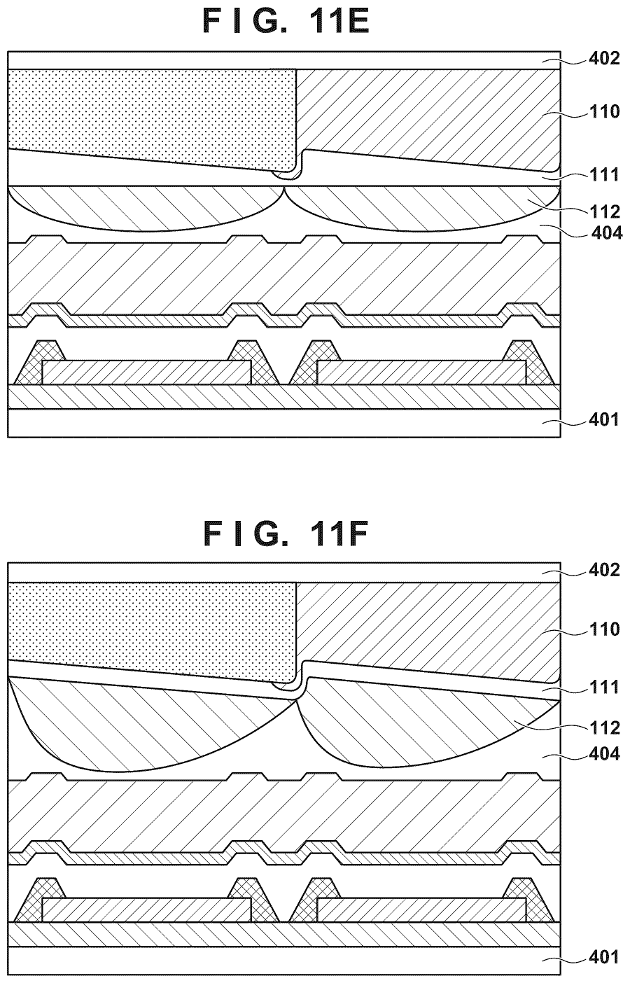

In the eighth embodiment as well, the tilt angle of the insulating film 403 may be adjusted in accordance with the position of the sub-pixel, the tilt angle of the insulating film 403 may be adjusted in accordance with the color of the sub-pixel, or a structure for reducing color mixture between adjacent sub-pixels may be formed. In the first to third configuration examples exemplarily shown in FIGS. 11A to 11C, a color filter 110 has an upper surface and a lower surface tilting with respect to the upper surface of a substrate 101. In the first to third configuration examples, the color filter 110 can have an even thickness in each sub-pixel. In the first to third configuration examples, the tilt angle of the upper surface and the lower surface of the color filter 110 can be adjusted or determined in accordance with the position in the light emitting region and/or in accordance with the color. In the first to third configuration examples exemplarily shown in FIGS. 11A to 11C, a normal to (the upper surface and the lower surface of) the color filter 110 tilts with respect to a normal to the light emitting region (display region) (or a normal to the upper surface of the substrate 101). The color filter 110 can be formed using, for example, a gray tone mask, as in a method of forming a second insulating film 109. To obtain the configuration exemplarily shown in FIG. 11A, an insulating film 403 having a tilting surface is formed on a second substrate 402, and a gray tone mask is used at the time of exposure for forming the color filter 110, thereby tilting the upper surface of the color filter. After that, a light emitting element and the color filter 110 on the second substrate 402 are bonded on the first substrate 401, thereby obtaining the configuration exemplarily shown in FIG. 11A.

As exemplarily shown in FIG. 11B, a transparent layer 111 and a microlens 112 may be arranged between the color filter 110 and a layer 404. To obtain the structure, first, the color filter 110 is formed on the second substrate 402 and, after that, the transparent layer 111 can be formed by applying a transparent resin. Alternatively, the transparent layer 111 may be formed by a layer of an inorganic material. After that, the microlens 112 can be formed by an exposure and development process. After the microlens 112 is formed, the microlens 112 and a light emitting element 120 can be bonded with the layer 404 intervening therebetween.

As exemplarily shown in FIG. 11C, the tilting transparent layer 111 and/or the tilting microlens 112 may be provided. The configuration of the tilting microlens 112 may be understood as a configuration in which the center axis of the microlens 112 tilts with respect to the normal to the light emitting region (display region) (or the normal to the upper surface of the substrate 101). The transparent layer 111 can be formed by forming a transparent resin having photosensitivity on the color filter 110 by spin coating and then exposing and developing the transparent resin using a gray tone mask. In addition, the microlens 112 can be formed by an exposure and development process using a gray tone mask or a reflow method. Since the tilt angle of the color filter 110 and the transparent layer 111 under the microlens 112 may change for each sub-pixel, the tilt angle of the microlens 112 may also change for each sub-pixel. However, the tilt angle of the microlens 112 need not always be equal to the tilt angle of the upper surfaces of the second insulating film 109 and the color filter 110. The tilt angle of the lower surface of the microlens 112 can be adjusted for each sub-pixel by adjusting the transmittance of the gray tone mask in a step of forming the transparent layer 111. The transparent layer 111 and the microlens 112 may be made of an inorganic material, and in this case, an inorganic film and an organic film are sequentially formed and, after that, the organic film is shaped, and the shape of the organic film is transferred to the inorganic film by etch back.

In the fourth to sixth configuration examples exemplarily shown in FIGS. 11D to 11F, the lower surface of the color filter 110 tilts with respect to the upper surface of the color filter 110. In this configuration, the insulating film 403 may not be provided but may be provided.

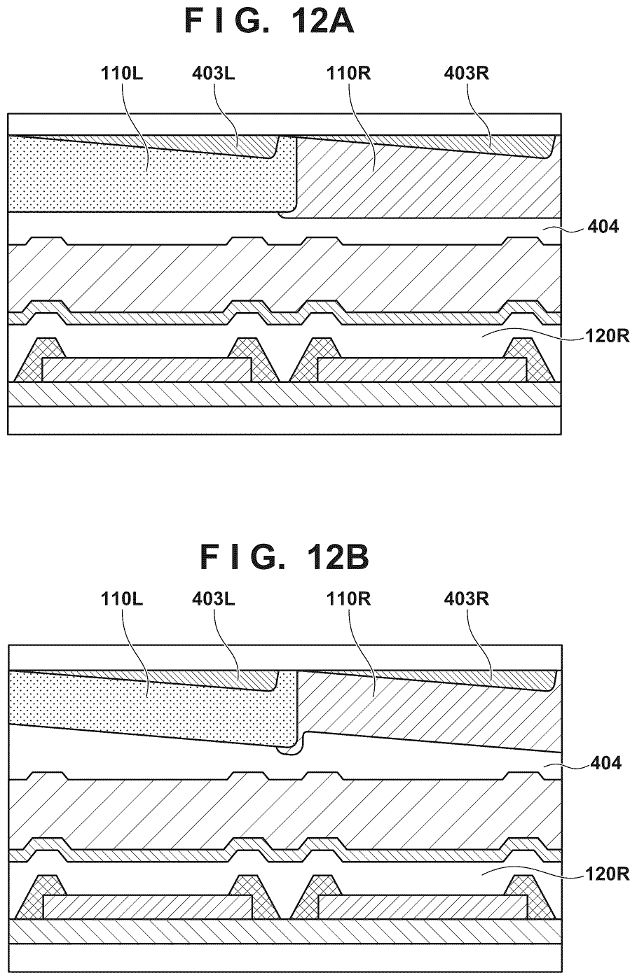

FIGS. 12A and 12B show the cross-sectional structures of two configuration examples of a light emitting device 100 according to the 10th embodiment. Matters that are not mentioned as the 10th embodiment can comply with one of the configurations of the first to ninth embodiments. The 10th embodiment has one feature in the structure of the boundary portion between insulating films 403L and 403R. Most of light emitted from a light emitting element 120R passes through a color filter 110R and the insulating film 403R and is emitted to the upper side. However, if the light emitted from the light emitting element 120R includes a component in an oblique direction, it changes to stray light upon passing through the color filter 110R and entering the insulating film 403L, and this may degrade display quality.

To improve this, a color filter 110L can be arranged in an optical path that directly passes from the color filter 110R to the insulating film 403L. This structure can be implemented by using as a reticle for an exposure step for forming the insulating films 403L and 403R, a reticle in which the pattern of each sub-pixels for defining an insulating film is arranged such that it is shrunk in the center direction of the sub-pixel.

As exemplarily shown in FIGS. 12A and 12B, the adjacent color filters 110L and 110R may overlap at the boundary portion. If the thickness of a transparent film 404 is large near the boundary portion between the adjacent color filters 110L and 110R, for example, part of light emitted from the light emitting element 120R may pass through the color filter 110L and enter the insulating film 403L, resulting in stray light. To reduce the stray light, the structure in which the adjacent color filters 110L and 110R overlap at the boundary portion is advantageous. This structure can be implemented by making the reticle transmittance near the boundary between the color filters different from that in other regions in a gray tone mask used in the exposure step for forming the color filters. If a negative resist is used as a color resist, the reticle transmittance near the boundary between the color filters is made higher than that in other regions. To the contrary, if a positive resist is used, the reticle transmittance near the boundary between the color filters is made lower than that in other regions.

The angle and position to tilt the insulating film 403 can be adjusted in accordance with the position and/or the color of the sub-pixel in the light emitting region. Also, in one sub-pixel, the shift amount between the center position of the light emitting element, the center position of the insulating film, and the center position of the color filter can be adjusted in accordance with the position and/or the color of the sub-pixel in the light emitting region. In the color filter, both the upper surface and the lower surface may be formed by tilting surfaces, or one of these may be formed by a tilting surface.

The organic light emitting element according to an embodiment of the present invention will be described next. The organic light emitting element according to the embodiment of the present invention includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*, or the like. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by measurement in which the compound to be measured is dissolved in a solvent such as toluene, and it is irradiated with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer is preferably used. Also, a material having a high glass transition point temperature is preferably used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

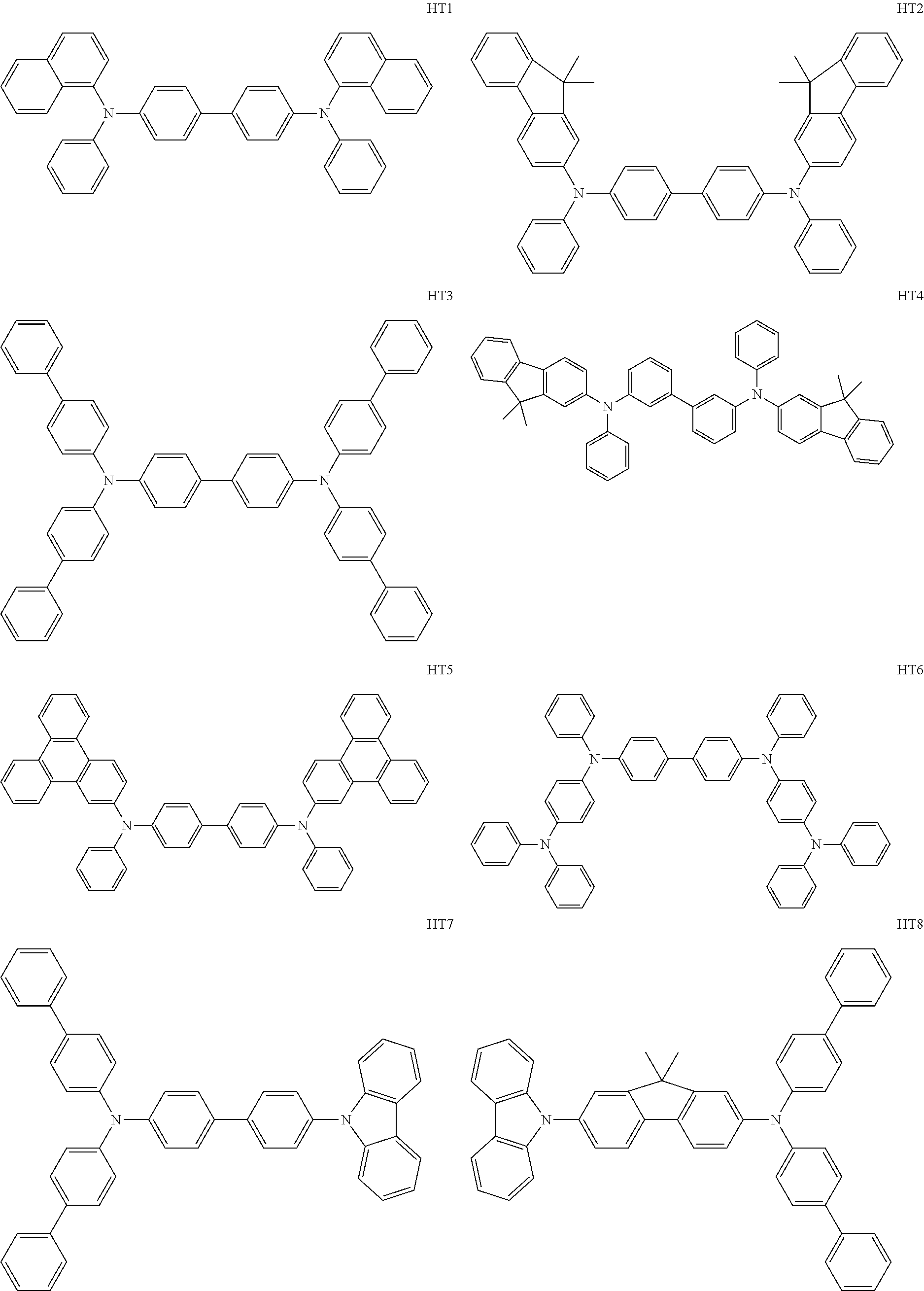

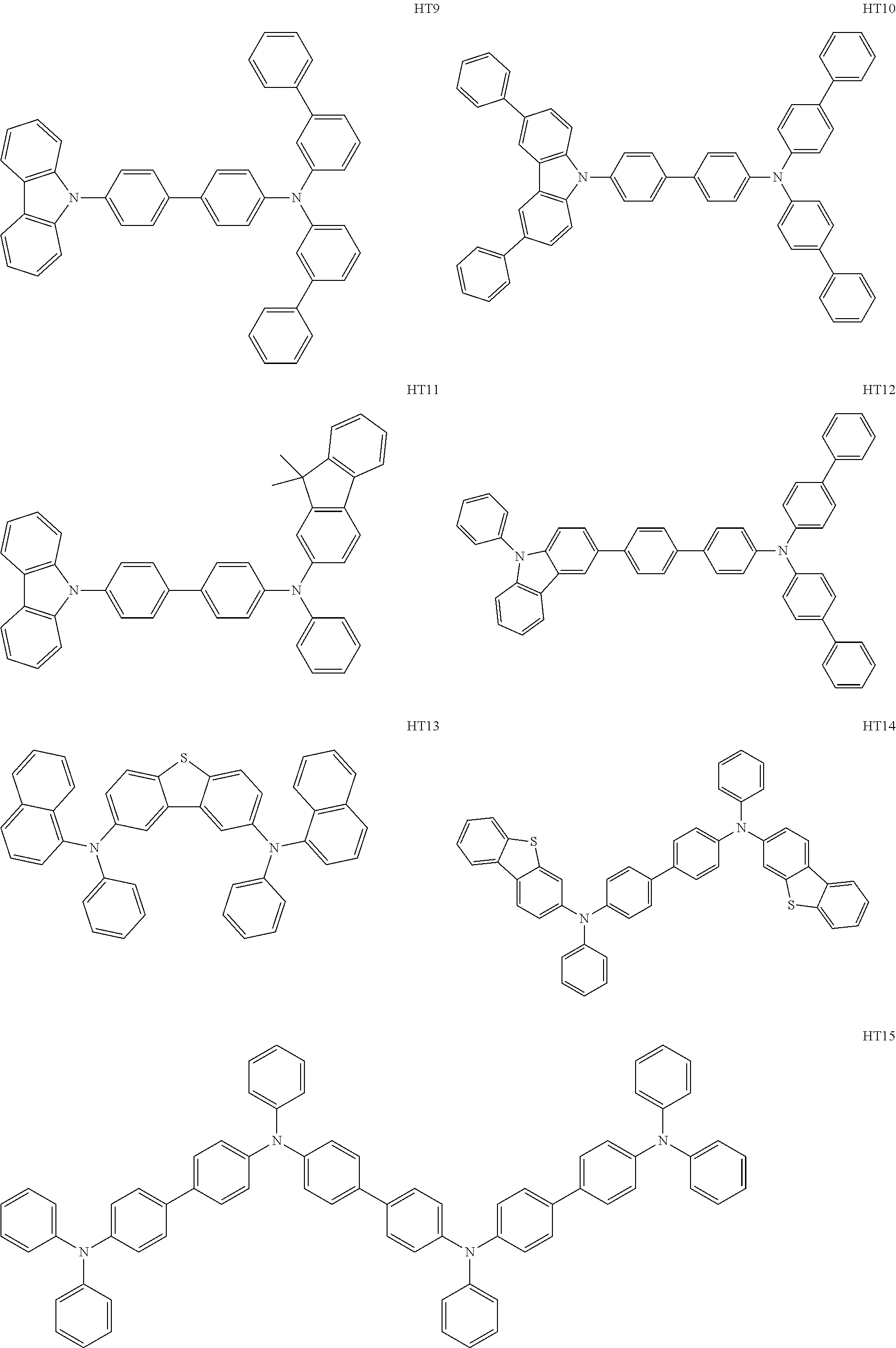

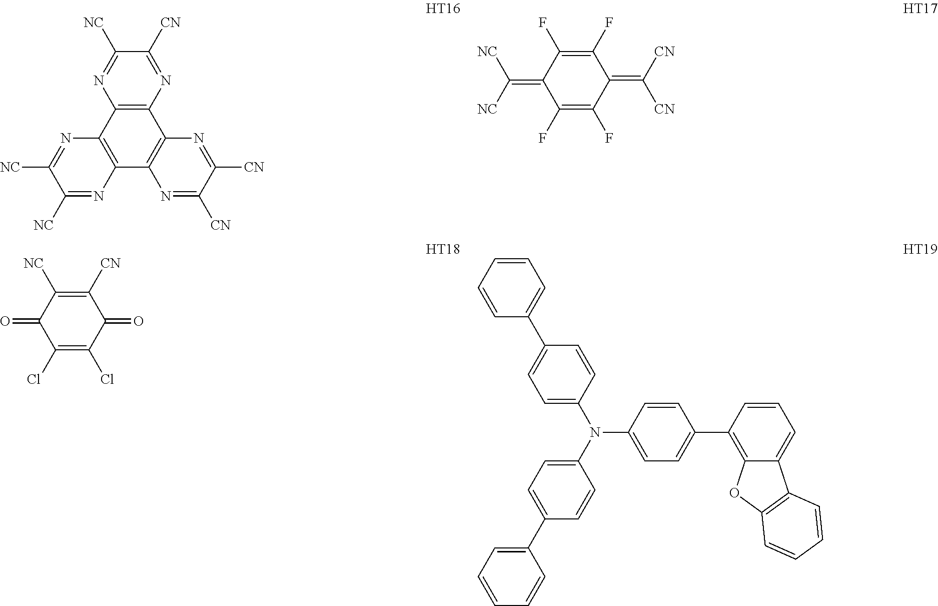

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

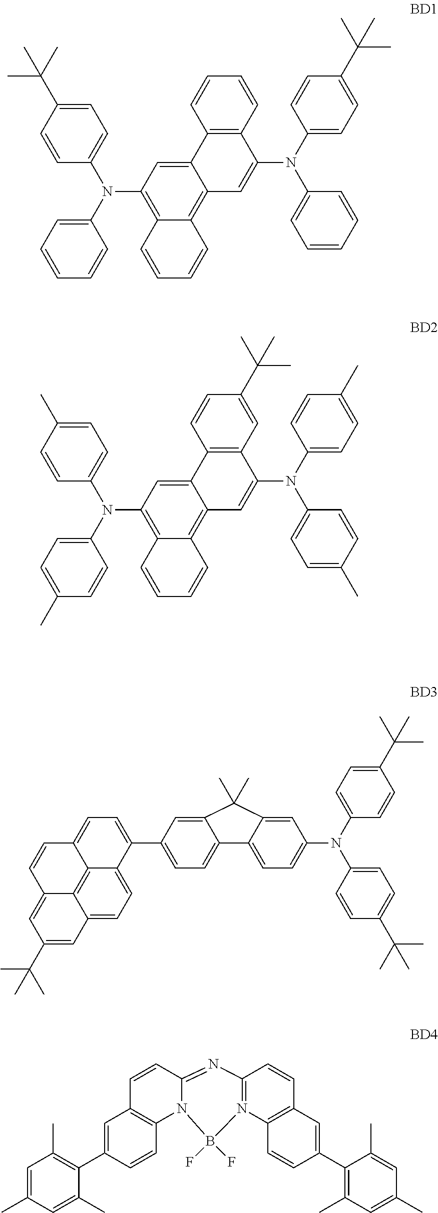

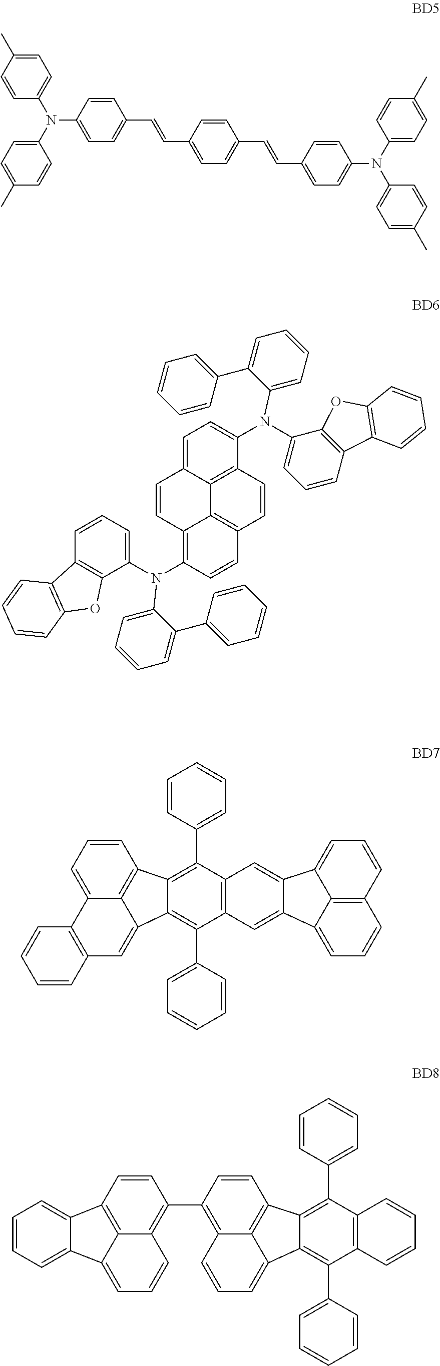

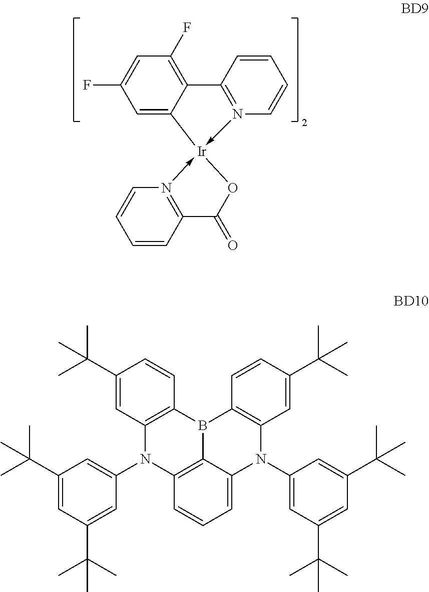

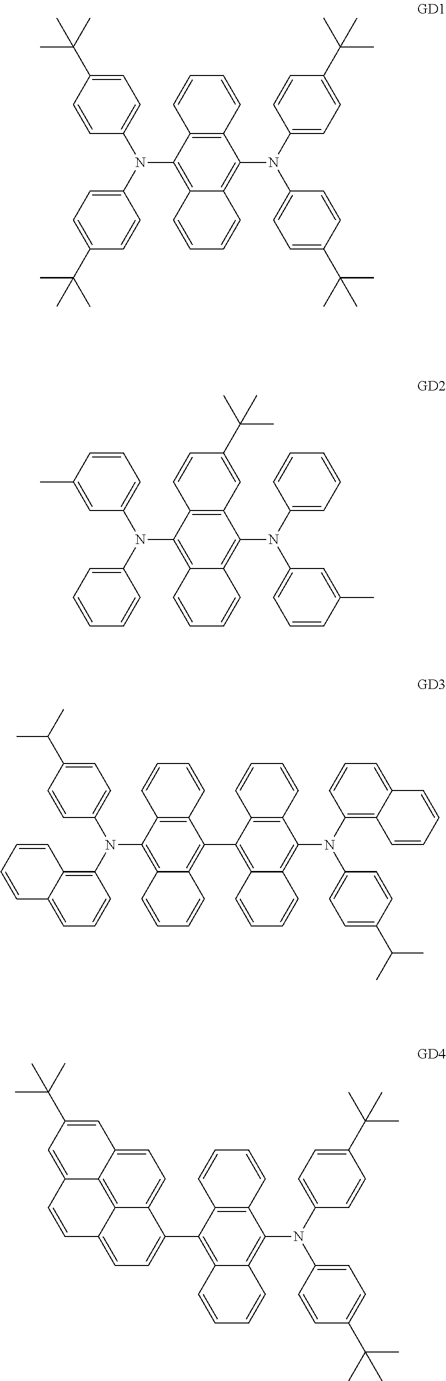

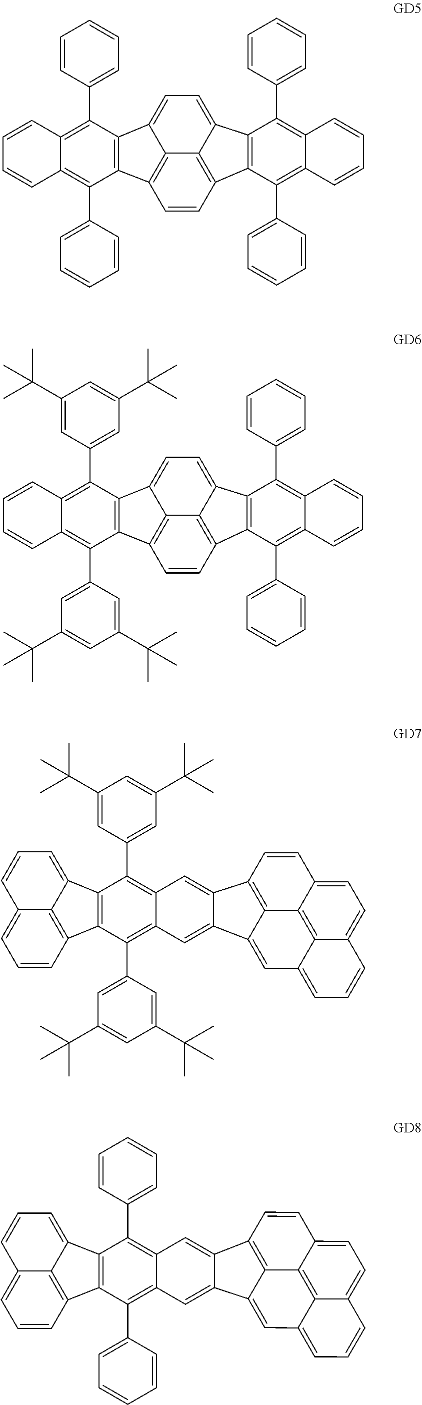

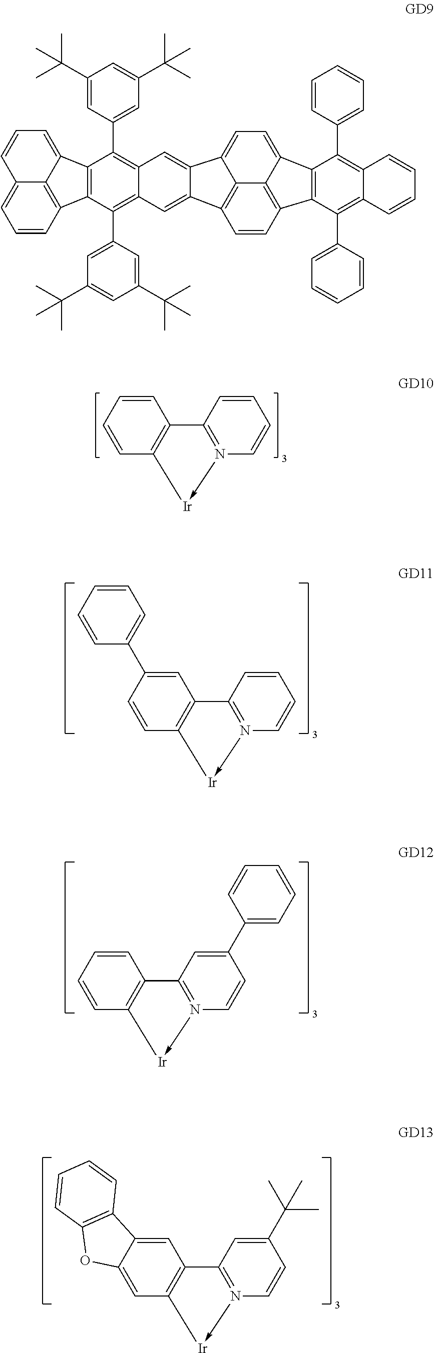

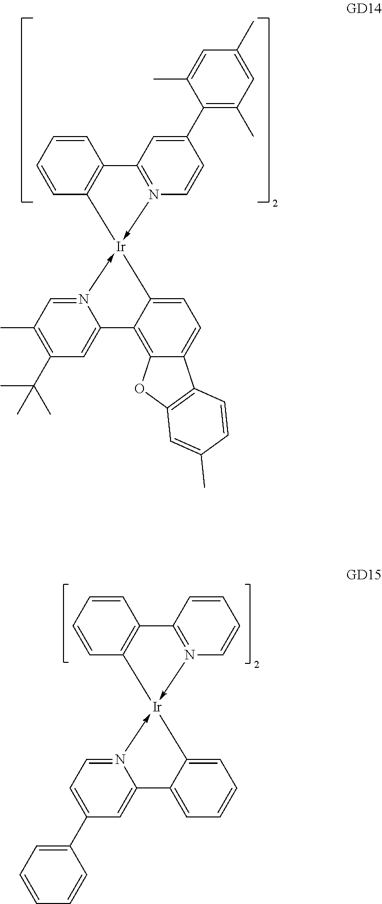

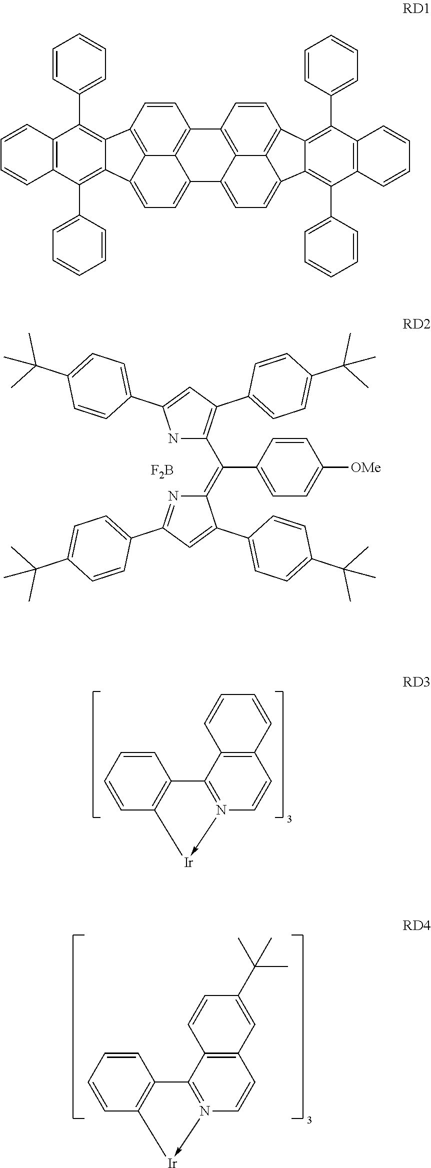

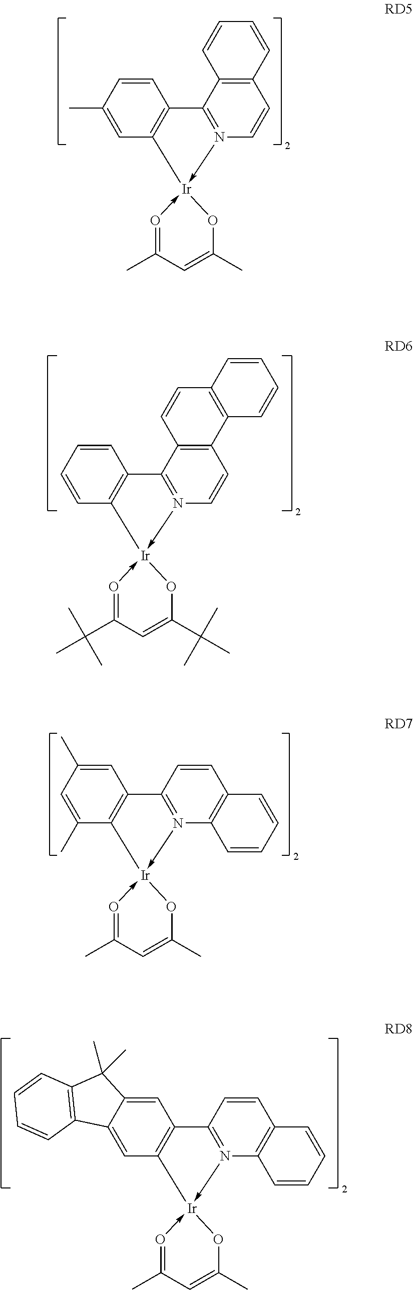

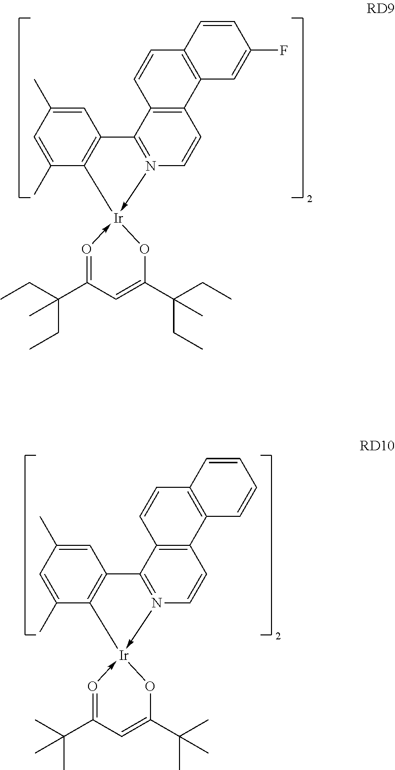

If the light emitting material is a hydrocarbon compound, this is preferable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is preferable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

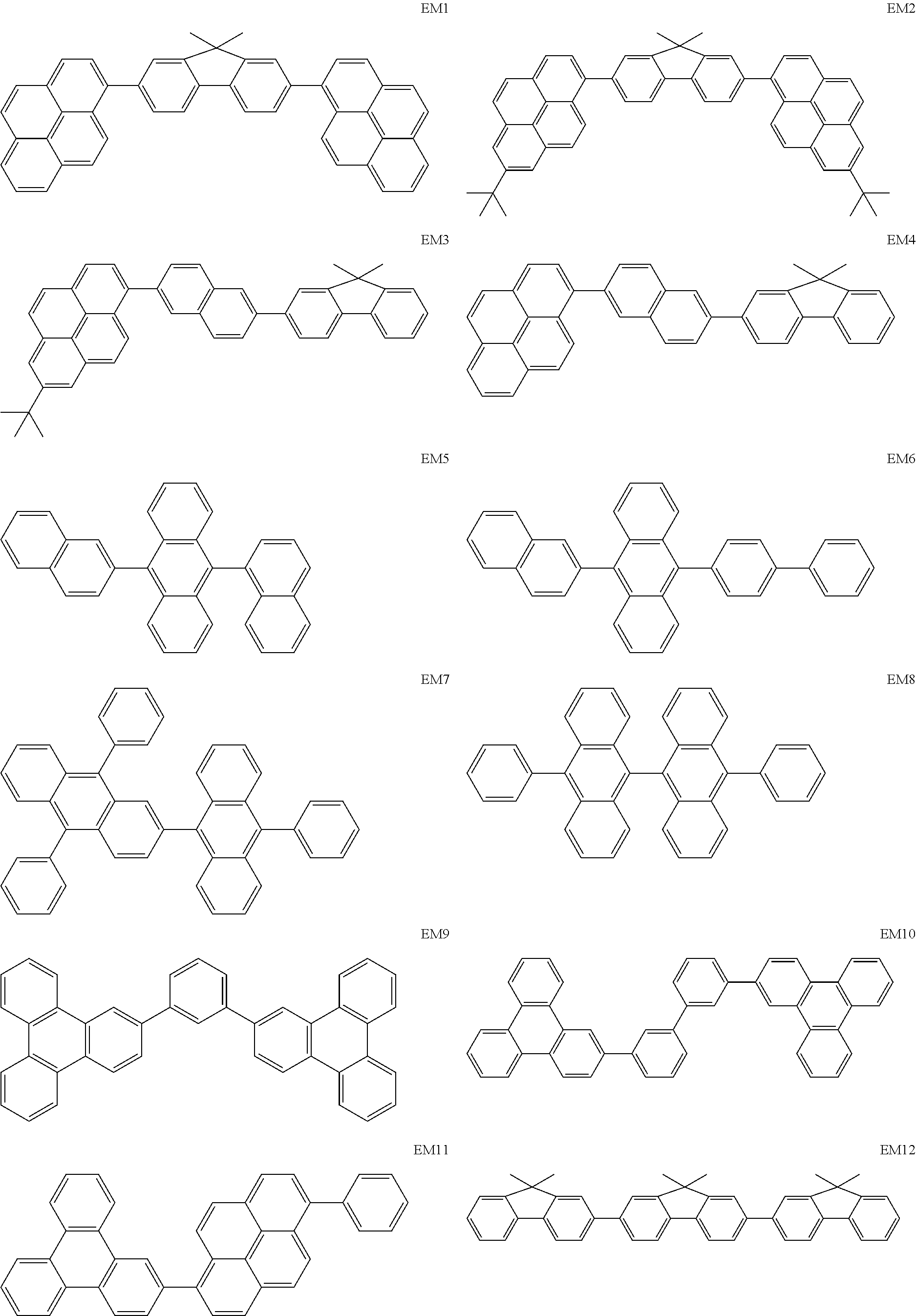

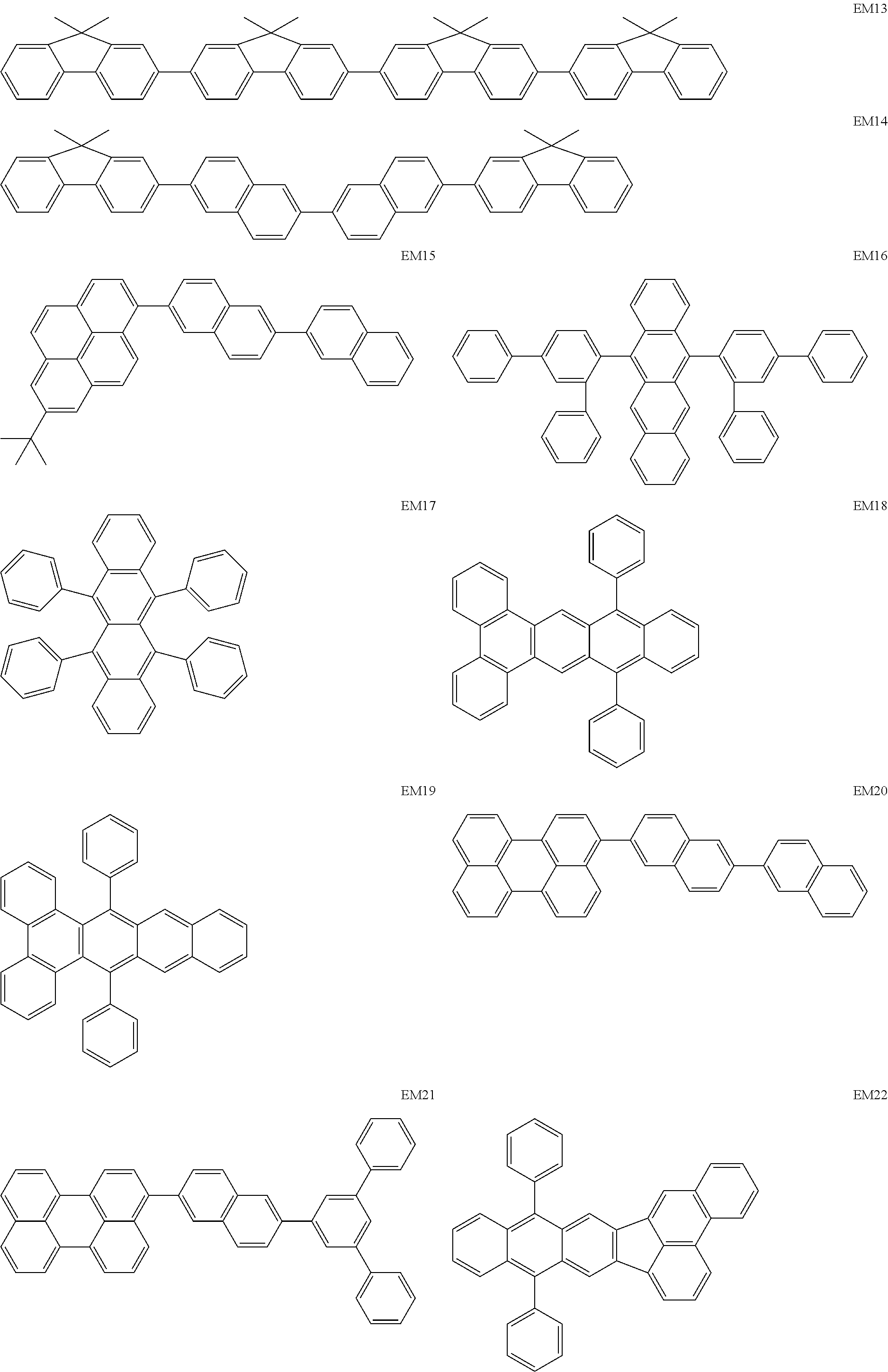

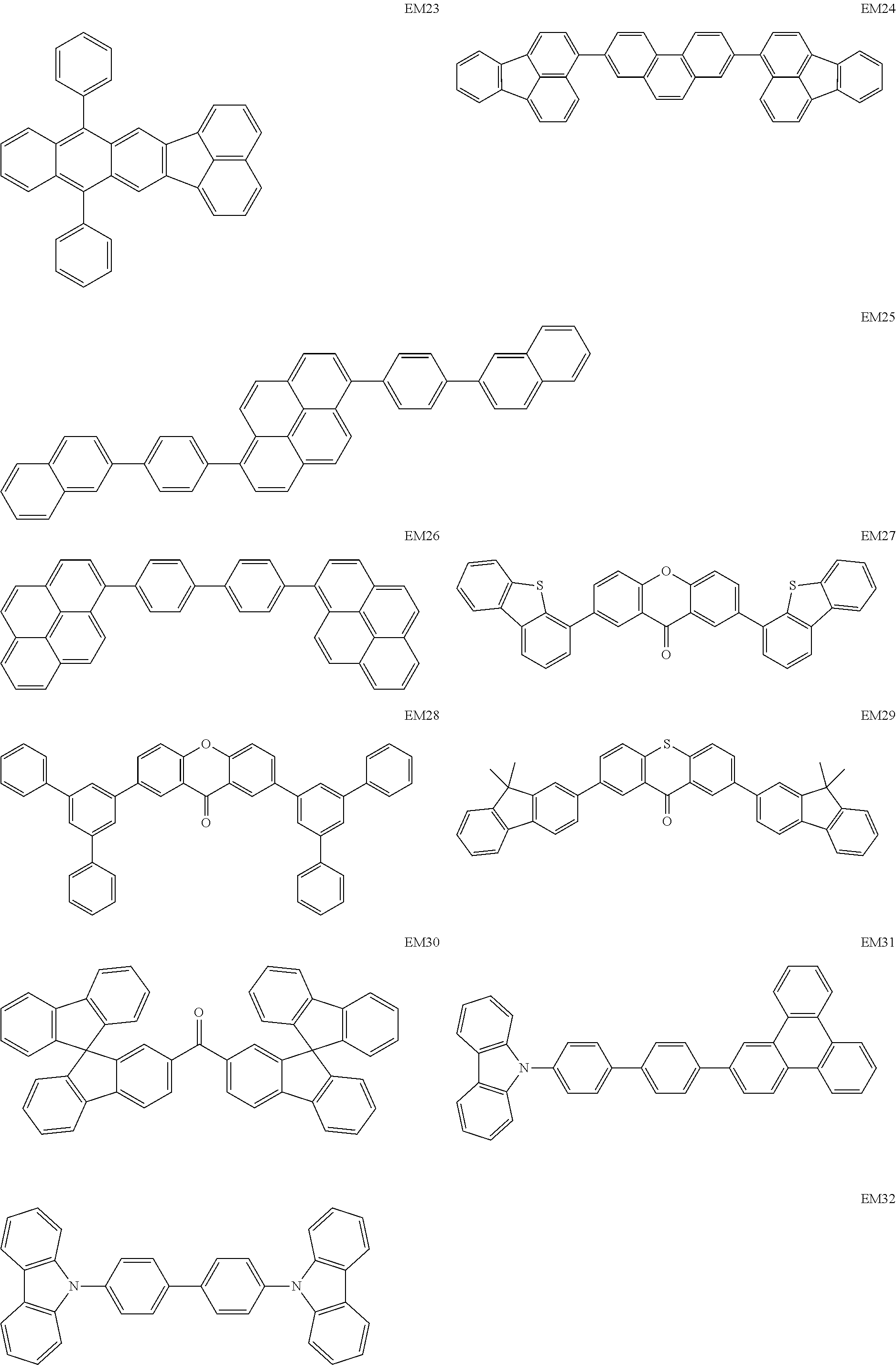

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

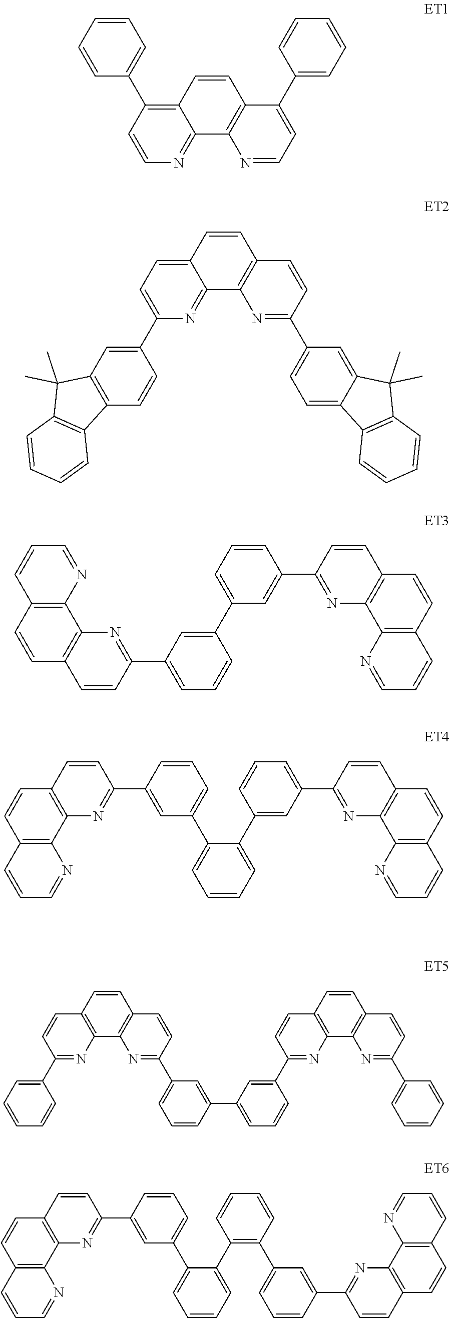

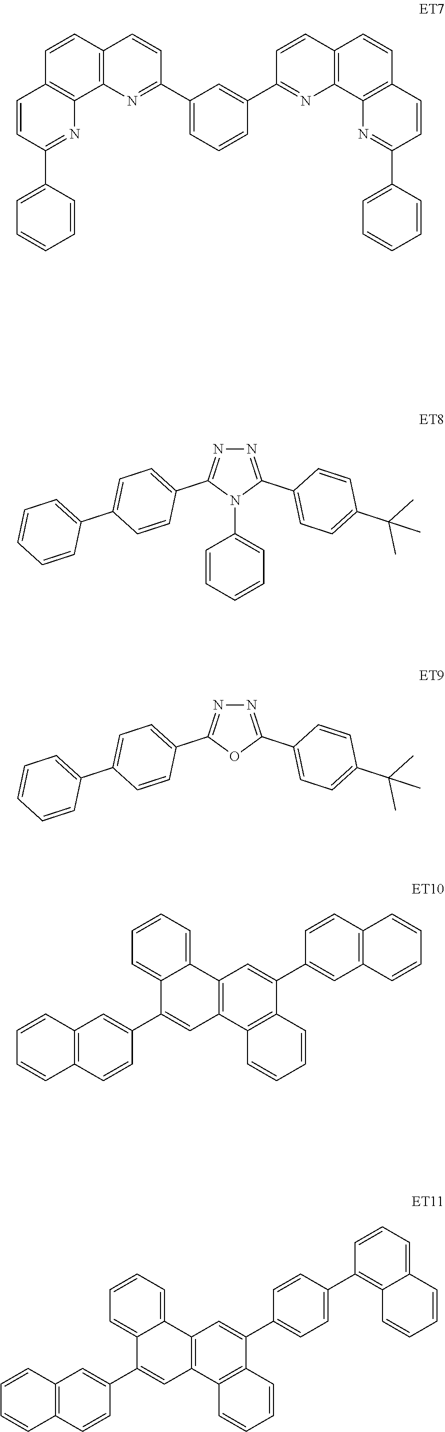

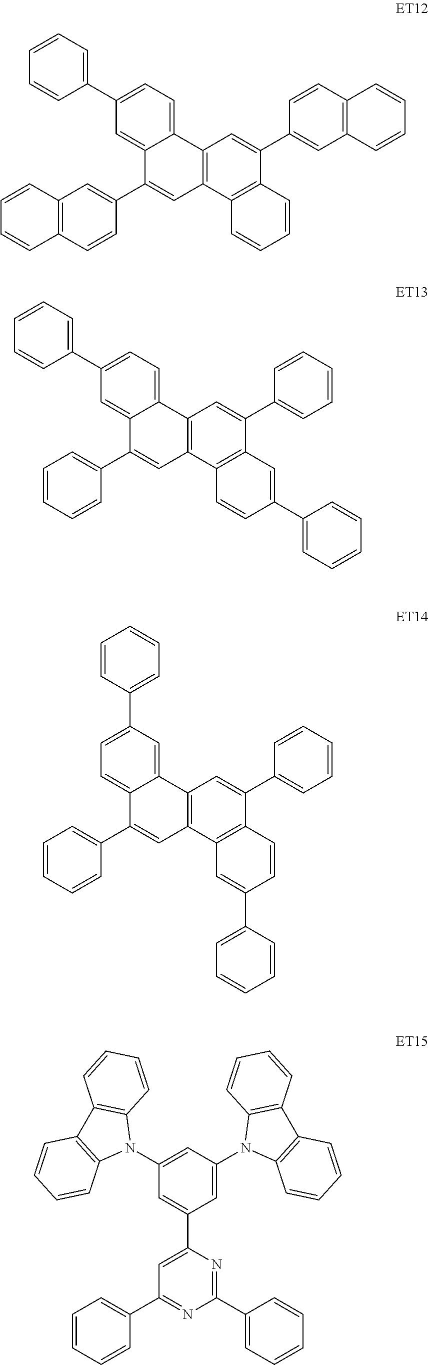

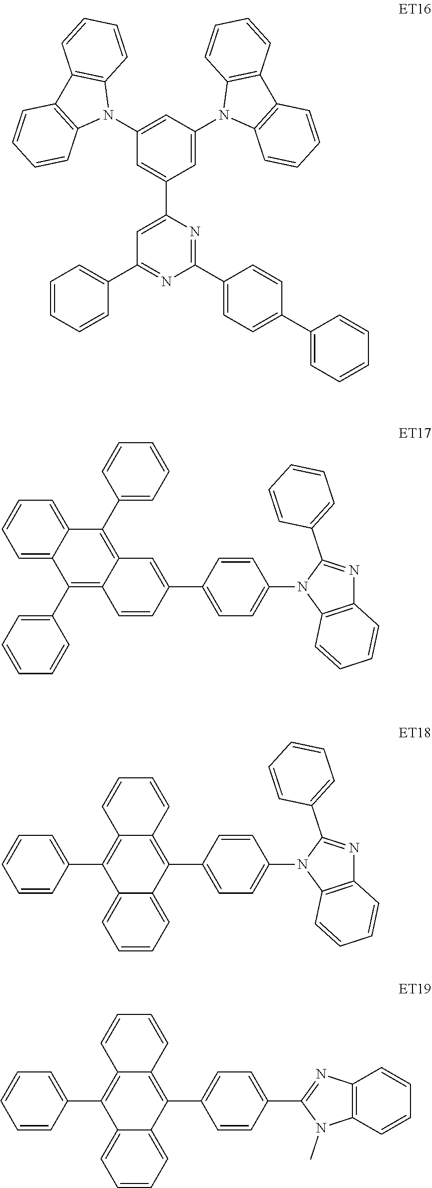 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2c3ccccc3c(-c3ccccc3)c3cc(-c4ccc(-n5c(-c6ccccc6)nc6ccccc65)cc4)ccc23)cc1 ; c1ccc(-c2c3ccccc3c(-c3ccc(-n4c(-c5ccccc5)nc5ccccc54)cc3)c3ccccc23)cc1 ; Cn1c(-c2ccc(-c3c4ccccc4c(-c4ccccc4)c4ccccc34)cc2)nc2ccccc21]

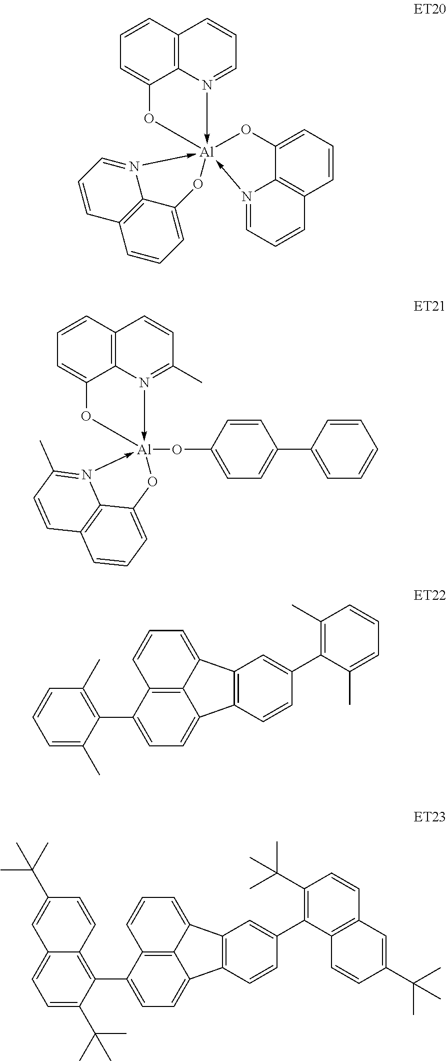

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### [Configuration of Organic Light Emitting Element]

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer can be provided between the protection layer and the color filter. The planarizing layer can be made of acrylic resin or the like. The same applies to a case in which a planarizing layer is provided between the color filter and the microlens.

### [Substrate]

Quartz, glass, a silicon wafer, a resin, a metal, or the like may be used as a substrate. Furthermore, a switching element such as a transistor and a wiring may be provided on the substrate, and an insulating layer may be provided thereon. The insulating layer may be made of any material as long as a contact hole can be formed so that the wiring can be formed between the insulating layer and the first electrode and insulation from the unconnected wiring can be ensured. For example, a resin such as polyimide, silicon oxide, silicon nitride, or the like can be used.

### [Electrode]

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a work function as large as possible is preferably used. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used.

One of these electrode materials may be used singly, or two or more of them may be used in combination. The anode may be formed by a single layer or a plurality of layers.

If the anode is used as a reflective electrode, for example, chromium, aluminum, silver, titanium, tungsten, molybdenum, an alloy thereof, a stacked layer thereof, or the like can be used. The above materials can function as a reflective film having no role as an electrode. If the anode is used as a transparent electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function is preferably used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Among others, silver is preferably used. To suppress aggregation of silver, a silver alloy is more preferably used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is preferably used since the good film coverage is provided and the resistance is easily lowered.

### [Pixel Isolation Layer]

A pixel isolation layer is formed by a silicon nitride (SiN) film, a silicon oxynitride (SiON) film, or a silicon oxide (SiO) film formed using a Chemical Vapor Deposition method (CVD method). To increase the resistance in the in-plane direction of the organic compound layer, the organic compound layer, especially the hole transport layer is preferably thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, it is preferable to adjust the taper angle of the side wall of the pixel isolation layer or the film thickness of the pixel isolation layer to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer is desirably 10 nm (inclusive) to 150 nm (inclusive). A similar effect can be obtained in a configuration including only pixel electrodes without the pixel isolation layer. However, in this case, the film thickness of the pixel electrode is preferably set to be equal to or smaller than half the film thickness of the organic layer or the end portion of the pixel electrode is preferably formed to have a forward tapered shape of less than 60° because short circuit of the organic light emitting element can be reduced.

### [Organic Compound Layer]

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generation portion is provided between the second light emitting layer and the third light emitting layer.

### [Protection Layer]

A protection layer may be provided on the second electrode. For example, by adhering glass provided with a moisture absorbing agent on the second electrode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 μm by a CVD method. The protection layer may be provided using an atomic deposition method (ALD method) after deposition using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

### [Planarizing Layer]

A planarizing layer may be provided between the color filter and the protection layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. However, a polymetric material is more preferable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

### [Microlens]

The organic light emitting device can include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface is preferably arranged on the functional layer side of the first surface. For this configuration, the microlens needs to be formed on the light emitting device. If the functional layer is an organic layer, it is preferable to avoid a process which produces high temperature in the manufacturing step. In addition, if it is configured to arrange the second surface on the functional layer side of the first surface, all the glass transition temperatures of an organic compound forming the organic layer are preferably 100° C. or more, and more preferably 130° C. or more.

### [Counter Substrate]

A counter substrate can be provided on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### [Organic Layer]

The organic compound layer (hole injection layer, hole transport layer, electron blocking layer, light emitting layer, hole blocking layer, electron transport layer, electron injection layer, and the like) forming the organic light emitting element according to an embodiment of the present invention is formed by the method to be described below.

The organic compound layer forming the organic light emitting element according to the embodiment of the present invention can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### [Pixel Circuit]

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### [Pixel]

The organic light emitting device includes a plurality of pixels. Each pixel includes sub-pixels that emit light components of different colors. The sub-pixels include, for example, R, G, and B emission colors, respectively.

In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. Here, these shapes need not be correct shapes, and a shape close to a rectangle is included in a rectangle. The shape of the sub-pixel and the pixel arrangement can be used in combination.

### [Application of Organic Light Emitting Element of Embodiment of Present Invention]

The organic light emitting element according to an embodiment of the present invention can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

An application example in which the above-described light emitting device is used as a display device or a light source will be exemplarily described below.

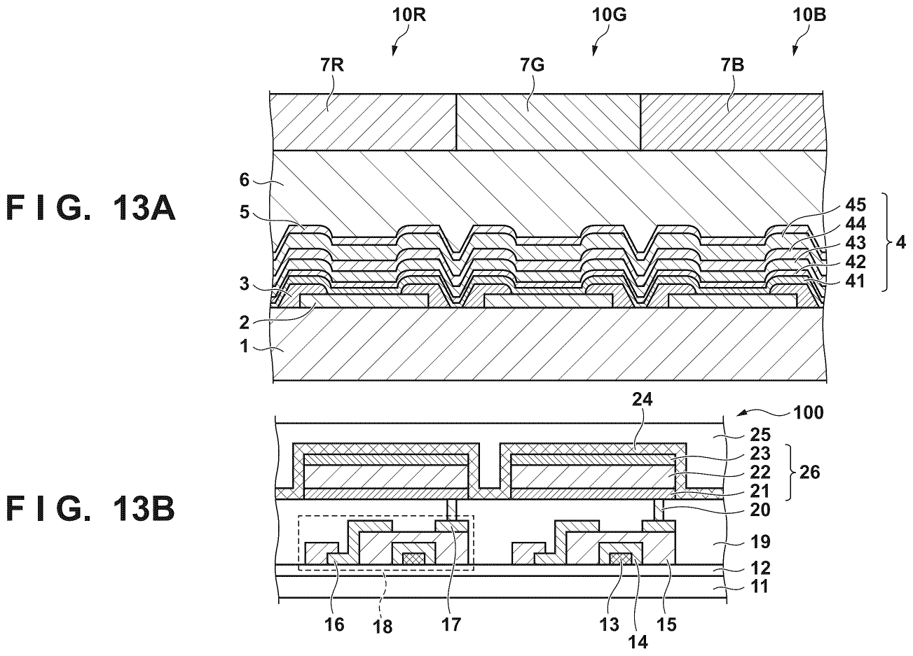

FIGS. 13A and 13B are schematic sectional views showing an example of a display device including an organic light emitting element and a transistor connected to the organic light emitting element. The transistor is an example of an active element. The transistor may be a thin-film transistor (TFT).

FIG. 13A shows an example of a pixel that is a constituent element of the display device according to this embodiment. The pixel includes sub-pixels 10. The sub-pixels are divided into sub-pixels 10R, 10G, and 10B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 2 as the first electrode on an interlayer insulating layer 1, an insulating layer 3 covering the end of the reflective electrode 2, an organic compound layer 4 covering the first electrode and the insulating layer, a transparent electrode 5 as the second electrode, a protection layer 6, and a color filter 7.

The interlayer insulating layer 1 can include a transistor and a capacitive element arranged in the interlayer insulating layer 1 or a layer below it. The transistor and the first electrode can electrically be connected via a contact hole (not shown) or the like.

The insulating layer 3 is also called a bank or a pixel isolation film. The insulating layer 3 covers the end of the first electrode, and is arranged to surround the first electrode. A portion where no insulating layer is arranged is in contact with the organic compound layer 4 to form a light emitting region.

The organic compound layer 4 includes a hole injection layer 41, a hole transport layer 42, a first light emitting layer 43, a second light emitting layer 44, and an electron transport layer 45.

The second electrode 5 may be a transparent electrode, a reflective electrode, or a semi-transmissive electrode.

The protection layer 6 suppresses permeation of water into the organic compound layer. The protection layer is shown as a single layer but may include a plurality of layers. Each layer can be an inorganic compound layer or an organic compound layer.

The color filter 7 is divided into color filters 7R, 7G, and 7B by colors. The color filters can be formed on a planarizing film (not shown). A resin protection layer (not shown) may be arranged on the color filters. The color filters can be formed on the protection layer 6. Alternatively, the color filters can be provided on the counter substrate such as a glass substrate, and then the substrate may be bonded.

The display device 100 shown in FIG. 13B is provided with an organic light emitting element 26 and a TFT 18 as an example of a transistor. A substrate 11 of glass, silicon, or the like is provided and an insulating layer 12 is provided on the substrate 11. An active element 18 such as a TFT is arranged on the insulating layer, and a gate electrode 13, a gate insulating film 14, and a semiconductor layer 15 of the active element are arranged. The TFT 18 further includes the semiconductor layer 15, a drain electrode 16, and a source electrode 17. An insulating film 19 is provided on the TFT 18. The source electrode 17 and an anode 21 forming the organic light emitting element 26 are connected via a contact hole 20 formed in the insulating film.

Note that a method of electrically connecting the electrodes (anode and cathode) included in the organic light emitting element 26 and the electrodes (source electrode and drain electrode) included in the TFT is not limited to that shown in FIG. 1B. That is, one of the anode and cathode and one of the source electrode and drain electrode of the TFT are electrically connected. The TFT indicates a thin-film transistor.

In the display device 100 shown in FIG. 13B, an organic compound layer is illustrated as one layer. However, an organic compound layer 22 may include a plurality of layers. A first protection layer 24 and a second protection layer 25 are provided on a cathode 23 to suppress deterioration of the organic light emitting element.

A transistor is used as a switching element in the display device 100 shown in FIG. 13B, but another switching element may be used instead.

The transistor used in the display device 100 shown in FIG. 13B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 100 shown in FIG. 13B may be formed in the substrate such as an Si substrate. Forming the transistor in the substrate means forming the transistor by processing the substrate such as an Si substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Note that the switching element according to this embodiment is not limited to the TFT, and may be a transistor formed from low-temperature polysilicon or an active matrix driver formed on the substrate such as an Si substrate. The term “on the substrate” may mean “in the substrate”. Whether to provide a transistor in the substrate or use a TFT is selected based on the size of the display unit. For example, if the size is about 0.5 inch, the organic light emitting element is preferably provided on the Si substrate.

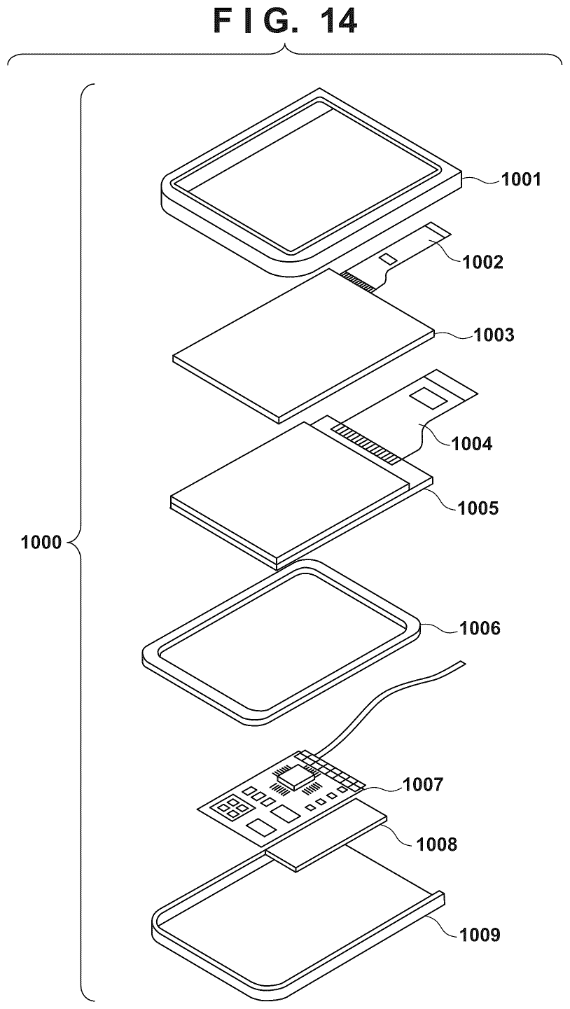

FIG. 14 is a schematic view showing an example of the display device according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display device is not a portable apparatus. Even when the display device is a portable apparatus, the battery 1008 may be provided at another position.

In the display device according to this embodiment, color filters may be arranged using a delta arrangement of red, green, and blue.

The display device according to this embodiment may be used as a display unit of a portable terminal. At this time, the display unit can have both a display function and an operation function. Examples of the portable terminal are a portable phone such as a smartphone, a tablet, and a head mounted display.

The display device according to this embodiment can be used for a display unit of an image capturing device including an optical unit having a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

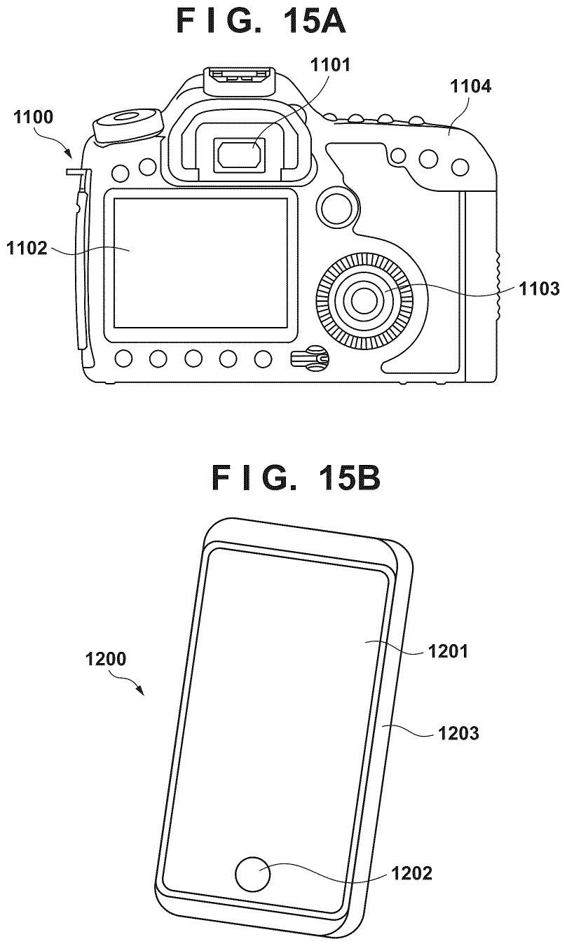

FIG. 15A is a schematic view showing an example of the image capturing device according to this embodiment. An image capturing device 1100 can include a viewfinder 1101, a rear display 1102, an operation unit 1103, and a housing 1104. The viewfinder 1101 may include the display device according to this embodiment. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display device using the organic light emitting element according to the present invention. This is so because the organic light emitting element has a high response speed. The display device using the organic light emitting element can be used for the devices that require a high display speed more preferably than for the liquid crystal display device.

The image capturing device 1100 includes an optical unit (not shown). This optical unit has a plurality of lenses, and forms an image on an image capturing element accommodated in the housing 1104. The focal points of the plurality of lenses can be adjusted by adjusting the relative positions. This operation can also automatically be performed. The image capturing device may be called a photoelectric conversion device. The photoelectric conversion device can include, as an image capturing method, not a method of sequentially capturing images but a method of detecting the difference from a preceding image, a method of extracting an image from an always recorded image, and the like.

FIG. 15B is a schematic view showing an example of an electronic apparatus according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The portable apparatus including the communication unit can also be regarded as a communication apparatus. The electronic apparatus may also have a camera function by including a lens and an image sensor. An image captured by the camera function is displayed on the display unit. Examples of the electronic apparatus are a smartphone and a laptop computer.

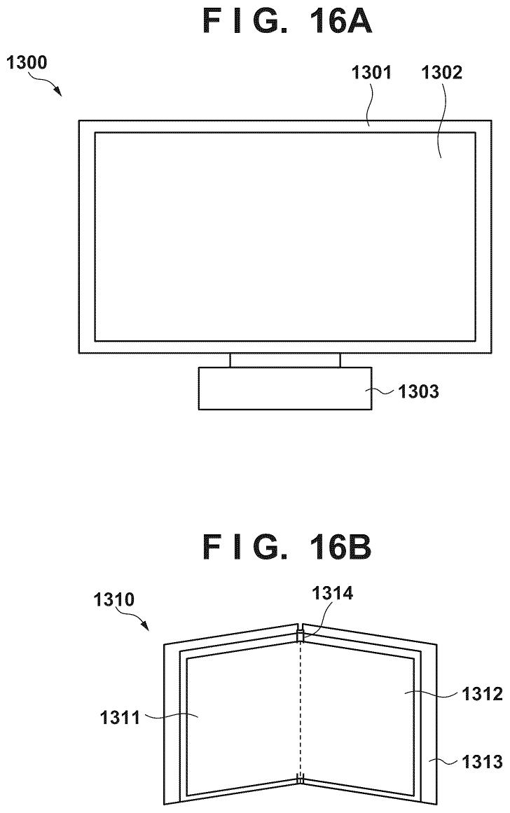

FIGS. 16A and 16B are schematic views showing examples of the display device according to this embodiment. FIG. 16A shows a display device such as a television monitor or a PC monitor. A display device 1300 includes a frame 1301 and a display unit 1302. The light emitting device according to this embodiment can be used for the display unit 1302.

The display device 1300 includes a base 1303 that supports the frame 1301 and the display unit 1302. The base 1303 is not limited to the form shown in FIG. 16A. The lower side of the frame 1301 may also function as the base.

In addition, the frame 1301 and the display unit 1302 can be bent. The radius of curvature in this case can be 5,000 mm (inclusive) to 6,000 mm (inclusive).

FIG. 16B is a schematic view showing another example of the display device according to this embodiment. A display device 1310 shown in FIG. 16B can be folded, and is a so-called foldable display device. The display device 1310 includes a first display unit 1311, a second display unit 1312, a housing 1313, and a bending point 1314. Each of the first display unit 1311 and the second display unit 1312 may include the light emitting device according to this embodiment. The first display unit 1311 and the second display unit 1312 can also be one seamless display device. The first display unit 1311 and the second display unit 1312 can be divided by the bending point. The first display unit 1311 and the second display unit 1312 can display different images, and the first and second display units can also display one image together.

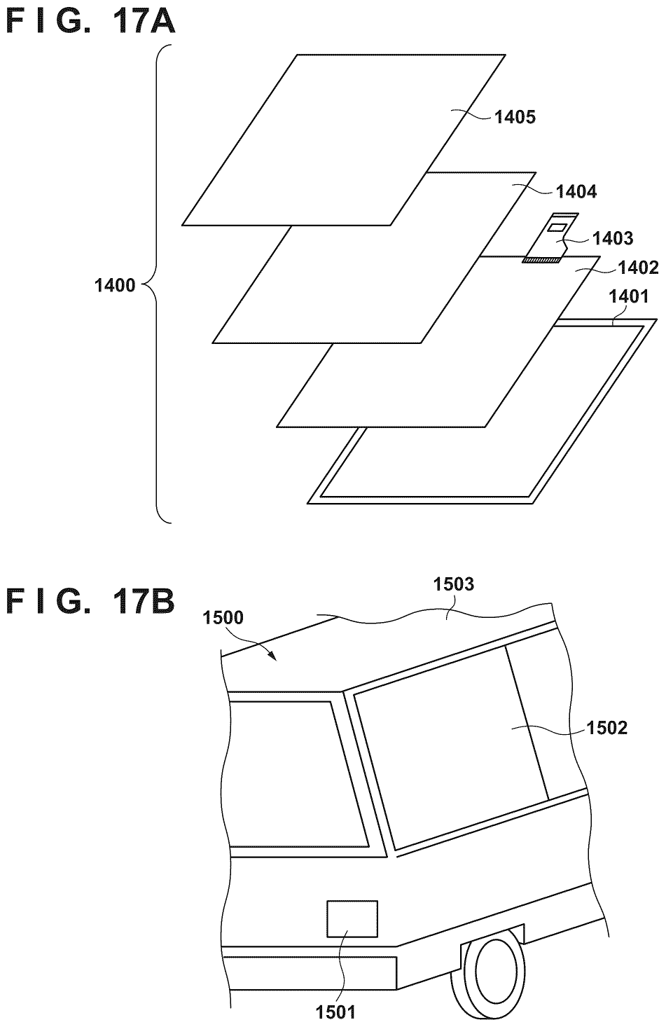

FIG. 17A is a schematic view showing an example of the illumination device according to this embodiment. An illumination device 1400 can include a housing 1401, a light source 1402, a circuit board 1403, an optical film 1404, and a light diffusing unit 1405. The light source may include the organic light emitting element according to this embodiment. The optical filter can be a filter that improves the color rendering of the light source. When performing lighting-up or the like, the light diffusing unit can throw the light of the light source over a broad range by effectively diffusing the light. The optical filter and the light diffusing unit may be provided on the light emission side of illumination. A cover may be provided on the outermost portion, as needed.

The illumination device is, for example, a device for illuminating the interior of the room. The illumination device can emit white light, natural white light, or light of any color from blue to red. The illumination device can also include a light control circuit for controlling these light components. The illumination device can also include the organic light emitting element according to the present invention, and a power supply circuit connected to it. The power supply circuit is a circuit for converting an AC voltage into a DC voltage. White has a color temperature of 4,200 K, and natural white has a color temperature of 5,000 K.

In addition, the illumination device according to this embodiment can include a heat radiation unit. The heat radiation unit radiates the internal heat of the device to the outside of the device, and examples are a metal having a high specific heat and liquid silicon.

FIG. 17B is a schematic view of an automobile that is an example of a moving body according to this embodiment. The automobile includes a taillight that is an example of a lighting appliance. An automobile 1500 has a taillight 1501, and can have a form in which the taillight is turned on when performing a braking operation or the like.

The taillight 1501 can include an organic light emitting element according to this embodiment. The taillight can include a protection member for protecting an organic EL element. The material of the protection member is not limited as long as the material is a transparent material with a strength that is high to some extent, and the protection member is preferably made of polycarbonate or the like. A furandicarboxylic acid derivative, an acrylonitrile derivative, or the like may be mixed in polycarbonate.

The automobile 1500 can include a vehicle body 1503, and a window 1502 attached to the vehicle body 1503. This window can be a window for checking the front and back of the automobile, and otherwise, can be a transparent display. The transparent display may include the organic light emitting element according to this embodiment. In this case, the constituent materials of the electrodes and the like of the organic light emitting element are formed by transparent members.

The moving body according to this embodiment may be a ship, an aircraft, a drone, or the like. The moving body may include a main body and a lighting appliance provided in the main body. The lighting appliance may emit light to show the position of the main body. The lighting appliance includes an organic light emitting element according to this embodiment.

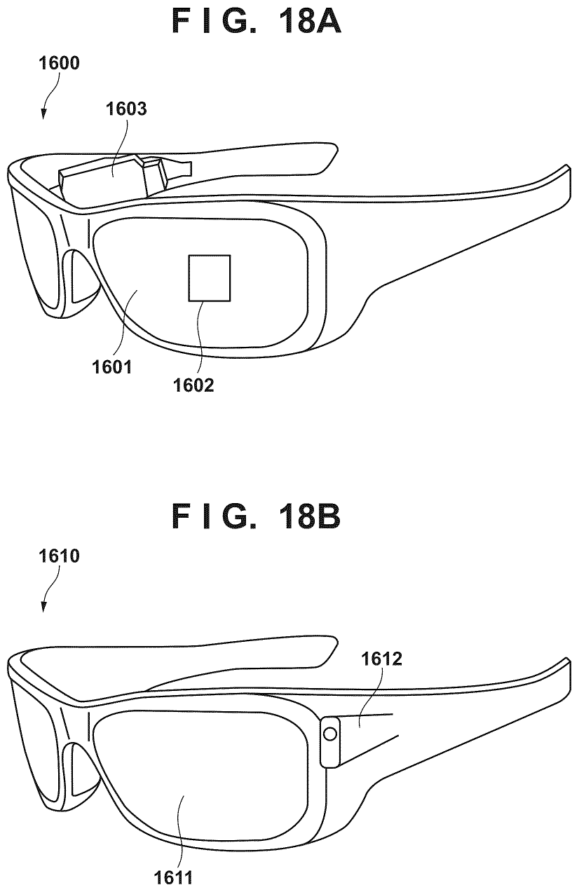

Application examples of the display device according to each embodiment described above will be described with reference to FIGS. 18A and 18B. The display device can be applied to a system that can be worn as a wearable device such as smartglasses, an HMD, or a smart contact lens. An image capturing display device used for such application examples includes an image capturing device capable of photoelectrically converting visible light and a display device capable of emitting visible light.

Glasses 1600 (smartglasses) according to one application example will be described with reference to FIG. 18A. An image capturing device 1602 such as a CMOS sensor or an SPAD is provided on the surface side of a lens 1601 of the glasses 1600. In addition, the display device according to each embodiment described above is provided on the back surface side of the lens 1601.

The glasses 1600 further include a control device 1603. The control device 1603 functions as a power supply that supplies electric power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 18B. The glasses 1610 include a control device 1612. An image capturing device corresponding to the image capturing device 1602 and the display device are mounted on the control device 1612. An optical system configured to project light emitted from the display device in the control device 1612 is formed in a lens 1611, and an image is projected to the lens 1611. The control device 1612 functions as a power supply that supplies electric power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention can include an image capturing device including a light receiving element, and control an image displayed on the display device based on the line-of-sight information of the user from the image capturing device.

More specifically, the display device decides a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, it can suitably be applied to smartglasses further including an image capturing device configured to capture the outside. The smartglasses can display captured outside information in real time.

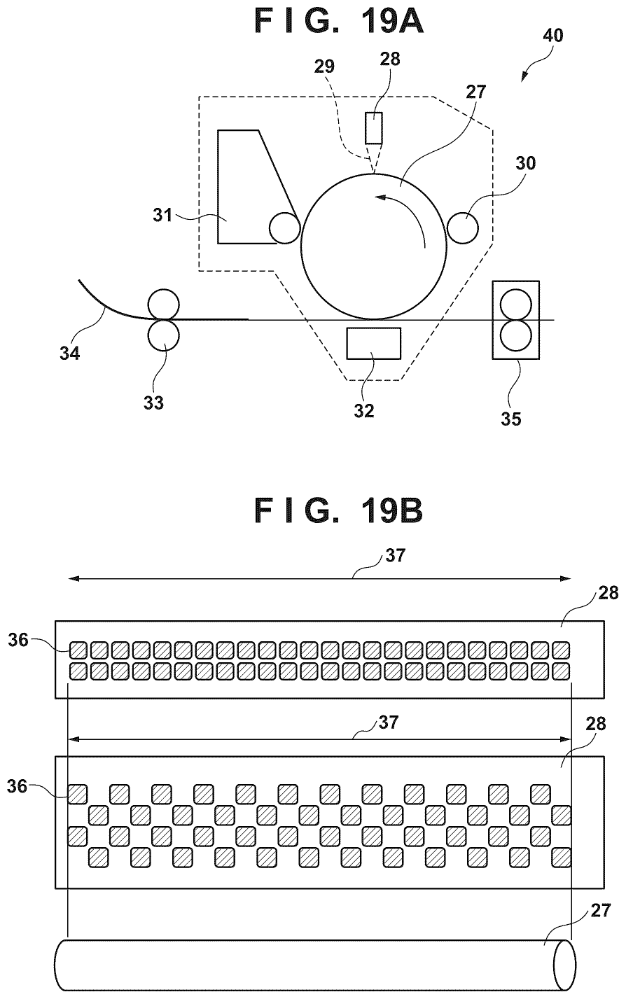

FIGS. 19A and 19B are schematic views showing an example of an image forming device using a light emitting device 1 according to this embodiment. An image forming device 40 shown in FIG. 19A includes a photosensitive member 27, an exposure light source 28, a developing unit 31, a charging unit 30, a transfer device 32, a conveyance unit 33 (a conveyance roller in the configuration shown in FIG. 19A), and a fixing device 35.

Light 29 is emitted from the exposure light source 28, and an electrostatic latent image is formed on the surface of the photosensitive member 27. The light emitting device 1 can be applied to the exposure light source 28. The developing unit 31 can function as a developing device that includes a toner or the like as a developing agent and applies the developing agent to the exposed photosensitive member 27. The charging unit 30 charges the photosensitive member 27. The transfer device 32 transfers the developed image to a print medium 34. The conveyance unit 33 conveys the print medium 34. The print medium 34 can be, for example, paper or a film. The fixing device 35 fixes the image formed on the print medium.

Each of FIG. 19B is a schematic view showing a plurality of light emitting units 36 arranged in the exposure light source 28 along the longitudinal direction of a long substrate. The light emitting device 1 can be applied to each of the light emitting units 36. That is, a plurality of pixels arranged to form a pixel array are arranged along the longitudinal direction of the substrate. A direction 37 is a direction parallel to the axis of the photosensitive member 27. This column direction matches the direction of the axis upon rotating the photosensitive member 27. The direction 37 can also be referred to as the long-axis direction of the photosensitive member 27.

The upper portion in FIG. 19B shows a form in which the light emitting units 36 are arranged along the long-axis direction of the photosensitive member 27. The middle portion in FIG. 19B shows a form, which is a modification of the arrangement of the light emitting units 36 shown in the upper portion in FIG. 19B, in which the light emitting units 36 are arranged in the column direction alternately in the first column and the second column. The light emitting units 36 are arranged at different positions in the row direction between the first column and the second column. In the first column, the plurality of light emitting units 36 are arranged spaced apart from each other. In the second column, the light emitting unit 36 is arranged at the position corresponding to the space between the light emitting units 36 in the first column. Furthermore, in the row direction, the plurality of light emitting units 36 are arranged spaced apart from each other. The arrangement of the light emitting units 36 shown in FIG. 19B can be referred to as, for example, an arrangement in a grid pattern, an arrangement in a staggered pattern, or an arrangement in a checkered pattern.

As described above, when a device using the organic light emitting element according to this embodiment is used, it is possible to perform stable display with high quality even in long time display.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-026909, filed Feb. 26, 2024, which is hereby incorporated by reference herein in its entirety.

What is claimed is:

1. A light emitting device comprising:
a light emitting region in which a plurality of sub-pixels are two-dimensionally arranged,
wherein each of the plurality of sub-pixels includes:
an organic layer including a light emitting layer;
a first insulating film arranged on the organic layer;
a second insulating film arranged on the first insulating film; and
a color filter arranged on the second insulating film, and
on a cross section passing through the first insulating film, the second insulating film, and the color filter, an upper surface of the second insulating film tilts with respect to a lower surface of the second insulating film.

2. The device according to claim 1, wherein the second insulating film and the color filter contain different materials.

3. The device according to claim 1, wherein
each of the plurality of sub-pixels further includes a microlens arranged on the color filter.

4. The device according to claim 1, wherein
the plurality of sub-pixels include a first sub-pixel, and a second sub-pixel arranged between the first sub-pixel and a center of the light emitting region, and
a tilt angle of the upper surface of the second insulating film of the first sub-pixel is different from the tilt angle of the upper surface of the second insulating film of the second sub-pixel.

5. The device according to claim 1, wherein
the plurality of sub-pixels include a first sub-pixel including a first color filter having a first color as the color filter, and a second sub-pixel including a second color filter having a second color as the color filter, and a tilt angle of the upper surface of the second insulating film of the first sub-pixel is different from the tilt angle of the upper surface of the second insulating film of the second sub-pixel.

6. The device according to claim 1, wherein
the plurality of sub-pixels include a first sub-pixel and a second sub-pixel, which are adjacent to each other, the first sub-pixel includes a first color filter as the color filter, and the second sub-pixel includes a second color filter whose color is different from the first color filter, and
the second insulating film of at least one of the first sub-pixel and the second sub-pixel has a structure for reducing color mixture between the first sub-pixel and the second sub-pixel.

7. The device according to claim 6, wherein
in the structure, at a boundary portion between the first color filter and the second color filter, the upper surface of the second insulating film of at least one of the first sub-pixel and the second sub-pixel totally reflects light from the light emitting layer of the other of the first sub-pixel and the second sub-pixel.

8. The device according to claim 6, wherein
in the structure, the second insulating film of at least one of the first sub-pixel and the second sub-pixel is not arranged at a boundary portion between the first color filter and the second color filter.

9. The device according to claim 1, wherein
each of the plurality of sub-pixels includes a lower electrode arranged under the organic layer, and the lower electrode is isolated from a lower electrode of an adjacent sub-pixel by an isolating portion with an opening, and
in the same sub-pixel, a center position of the opening, a center position of the second insulating film, and a center position of the color filter are shifted from each other.

10. The device according to claim 3, wherein
each of the plurality of sub-pixels includes a lower electrode arranged under the organic layer, and the lower electrode is isolated from a lower electrode of an adjacent sub-pixel by an isolating portion with an opening, and
in the same sub-pixel, a center position of the opening, a center position of the second insulating film, a center position of the color filter, and a center position of the microlens are shifted from each other.

11. The device according to claim 1, wherein
a normal to the color filter tilts with respect to a normal to the light emitting region.

12. The device according to claim 3, wherein
a normal to the color filter and a center axis of the microlens tilt with respect to a normal to the light emitting region.

13. A light emitting device comprising:
a light emitting region in which a plurality of sub-pixels are two-dimensionally arranged,
wherein each of the plurality of sub-pixels includes:
an organic layer including a light emitting layer;
a first insulating film arranged on the organic layer;
a color filter arranged on the first insulating film; and
a second insulating film arranged on the color filter, and
on a cross section passing through the first insulating film, the color filter, and the second insulating film, an upper surface of the color filter tilts with respect to a lower surface of the color filter.

14. The device according to claim 13, wherein the first insulating film and the second insulating film contain a material different from the color filter.

15. The device according to claim 13, further comprising a microlens arranged between the first insulating film and the color filter.

16. The device according to claim 13, wherein
the plurality of sub-pixels include a first sub-pixel, and a second sub-pixel arranged between the first sub-pixel and a center of the light emitting region, and
a tilt angle of an upper surface of the first insulating film of the first sub-pixel is different from the tilt angle of the upper surface of the first insulating film of the second sub-pixel.

17. The device according to claim 13, wherein
the plurality of sub-pixels include a first sub-pixel and a second sub-pixel, which are adjacent to each other, the first sub-pixel includes a first color filter having a first color as the color filter, and the second sub-pixel includes a second color filter having a second color as the color filter, and
the second insulating film of at least one of the first sub-pixel and the second sub-pixel has a structure for reducing color mixture between the first sub-pixel and the second sub-pixel.

18. The device according to claim 13, wherein
each of the plurality of sub-pixels includes a lower electrode arranged under the organic layer, and the lower electrode is isolated from a lower electrode of an adjacent sub-pixel by an isolating portion with an opening, and
in the same sub-pixel, a center position of the opening, a center position of the second insulating film, and a center position of the color filter are shifted from each other.

19. The device according to claim 15, wherein
each of the plurality of sub-pixels includes a lower electrode arranged under the organic layer, and the lower electrode is isolated from a lower electrode of an adjacent sub-pixel by an isolating portion with an opening, and
in the same sub-pixel, a center position of the opening, a center position of the second insulating film, a center position of the color filter, and a center position of the microlens are shifted from each other.

20. The device according to claim 13, wherein
a normal to the color filter tilts with respect to a normal to the light emitting region.

21. The device according to claim 15, wherein
a normal to the color filter and a center axis of the microlens tilt with respect to a normal to the light emitting region.

22. A photoelectric conversion device comprising an optical unit including a plurality of lenses, an image sensor configured to receive light having passed through the optical unit, and a display unit configured to display an image according to an image captured by the image sensor,
wherein the display unit is formed by a light emitting device defined in claim 1.

23. An electronic apparatus comprising a light emitting device defined in claim 1, a housing provided with the light emitting device, and a communication unit provided in the housing and configured to perform external communication,
wherein the light emitting device is formed as a display device.

24. An illumination device comprising a light emitting device defined in claim 1, and one of a light diffusing unit and an optical film configured to transmit light emitted by the light emitting device.

25. A moving body comprising a lighting appliance including a light emitting device defined in claim 1, and a main body provided with the lighting appliance.
